(19) United States
(12) Patent Application Publication
(10) Pub. No.: US 2025/0300102 A1
(43) Pub. Date: Sep. 25, 2025

(54) INTEGRATED DEVICE COMPRISING METALLIZATION PORTION

(71) Applicant: QUALCOMM Incorporated, San Diego, CA (US)

(72) Inventors: Yangyang SUN, San Diego, CA (US); Dongming HE, San Diego, CA (US); Lily ZHAO, San Diego, CA (US)

(21) Appl. No.: 18/611,416

(22) Filed: Mar. 20, 2024

(51) Int. Cl. H01L 23/00; H01L 21/56; H01L 23/31; H01L 25/00; H01L 25/065

(52) U.S. Cl. CPC H01L 24/02; H01L 23/3185; H01L 24/05; H01L 24/06; H01L 24/13; H01L 24/16; H01L 25/0657; H01L 25/50; H01L 21/561; H01L 24/03; H01L 24/11; H01L 24/14; H01L 24/32; H01L 24/73; H01L 24/81; H01L 24/92; H01L 24/96; H01L 2224/02313; H01L 2224/02375; H01L 2224/02381; H01L 2224/0346; H01L 2224/0401; H01L 2224/05008; H01L 2224/05024; H01L 2224/05147; H01L 2224/05562; H01L 2224/05569; H01L 2224/0557; H01L 2224/05647; H01L 2224/0603; H01L 2224/11849; H01L 2224/13023; H01L 2224/1403; H01L 2224/16145; H01L 2224/16227; H01L 2224/32225; H01L 2224/73204; H01L 2224/81815; H01L 2224/92125; H01L 2224/95001; H01L 2224/96; H01L 2225/06513; H01L 2225/06541

(57) ABSTRACT

An integrated device comprising a die substrate; a die interconnection coupled to the die substrate; an encapsulation layer coupled to a side surface of the die substrate and a side surface of the die interconnection; a plurality of pad interconnects coupled to the die interconnection; and a plurality of metallization interconnects, wherein one or more metallization interconnects from the plurality of metallization interconnects is coupled to one or more pad interconnects from the plurality of pad interconnects.

### FIELD

Various features relate to integrated devices.

### BACKGROUND

An integrated device is configured to perform various electrical functions. The performance of the integrated device and how it performs these various electrical functions will depend on how interconnects are arranged. There is an ongoing need to improve the performance of an integrated device while also reduce the overall form factor of the integrated device.

### SUMMARY

Various features relate to integrated devices.

One example provides an integrated device comprising a die substrate; a die interconnection coupled to the die substrate; an encapsulation layer coupled to a side surface of the die substrate and a side surface of the die interconnection; a plurality of pad interconnects coupled to the die interconnection; and a plurality of metallization interconnects, wherein one or more metallization interconnects from the plurality of metallization interconnects is coupled to one or more pad interconnects from the plurality of pad interconnects.

Another example provides a package comprising a first integrated device comprising: a die substrate; a die interconnection coupled to the die substrate; an encapsulation layer coupled to a side surface of the die substrate and a side surface of the die interconnection; a plurality of pad interconnects coupled to the die interconnection; and a plurality of metallization interconnects, wherein one or more metallization interconnects is coupled to one or more pad interconnects from the plurality of pad interconnects; and a second integrated device coupled to the first integrated device through a plurality of solder interconnects.

Another example provides a device comprising a die substrate; a die interconnection coupled to the die substrate; an encapsulation layer coupled to a side surface of the die substrate and a side surface of the die interconnection; a plurality of pad interconnects coupled to the die interconnection; and a plurality of metallization interconnects, wherein one or more metallization interconnects from the plurality of metallization interconnects is coupled to one or more pad interconnects from the plurality of pad interconnects.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross sectional profile view of an exemplary integrated device.

FIG. 2 illustrates a cross sectional profile view of an exemplary integrated device.

FIG. 3 illustrates a cross sectional profile view of an exemplary integrated device.

FIG. 4 illustrates a cross sectional plan view of an exemplary integrated device.

FIG. 5 illustrates a cross sectional plan view of an exemplary integrated device.

FIG. 6 illustrates an exemplary plan view of a hub and spoke configuration.

FIG. 7 illustrates an exemplary plan view of a hub and spoke configuration.

FIG. 8 illustrates an exemplary plan view of an arrangement of interconnects.

FIG. 9 illustrates an exemplary plan view of an arrangement of interconnects.

FIG. 10 illustrates an exemplary plan view of an arrangement of interconnects.

FIG. 11 illustrates a cross sectional profile view of an exemplary integrated device.

FIG. 12 illustrates a cross sectional profile view of an exemplary integrated device.

FIGS. 13A-13I illustrate an exemplary sequence for fabricating an integrated device.

FIG. 14 illustrates an exemplary flow diagram of a method for fabricating an integrated device.

FIG. 15 illustrates a cross sectional plan view of an exemplary integrated device.

FIG. 16 illustrates a cross sectional plan view of an exemplary package comprising several integrated devices.

FIGS. 17A-17C illustrate an exemplary sequence for fabricating a package comprising several integrated devices.

FIG. 18 illustrates an exemplary flow diagram of a method for fabricating a package comprising several integrated devices.

FIG. 19 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes an integrated device comprising a die substrate; a die interconnection coupled to the die substrate; an encapsulation layer coupled to a side surface of the die substrate and a side surface of the die interconnection; a plurality of pad interconnects coupled to the die interconnection; and a plurality of metallization interconnects, wherein one or more metallization interconnects from the plurality of metallization interconnects is coupled to one or more pad interconnects from the plurality of pad interconnects. In some implementations, the integrated device provides a reduced and/or minimized number of metal layers for metallization interconnects, in a compact form factor, while providing improved performance for the integrated device.

### Exemplary Integrated Devices

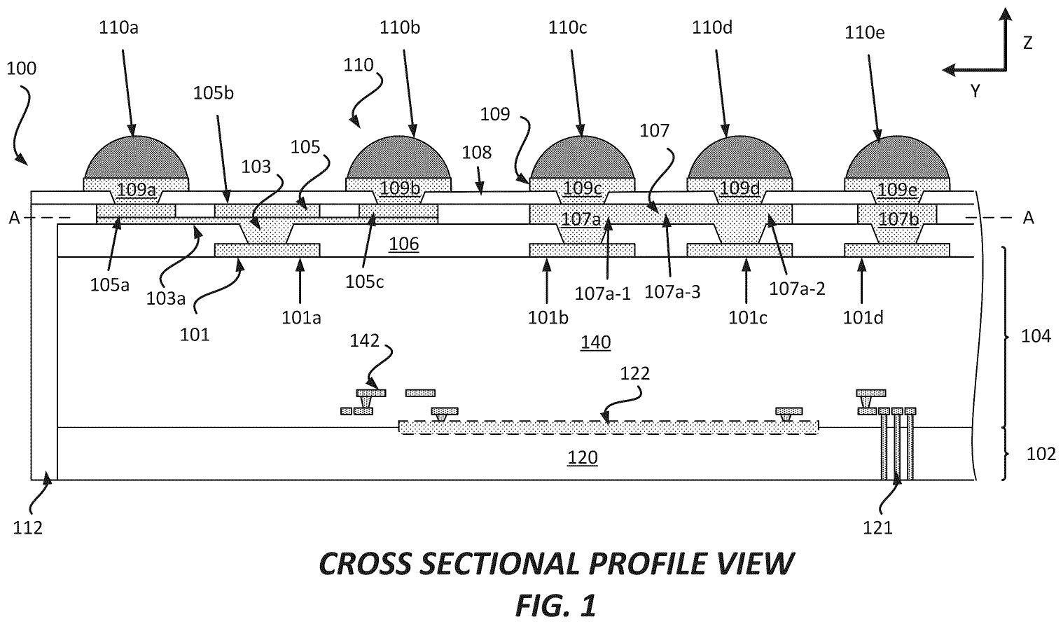

FIG. 1 illustrates a cross sectional profile view of an integrated device 100. The integrated device 100 includes a die substrate base 102 and a die interconnection 104. The die substrate base 102 includes a die substrate 120, an active region 122 and a plurality of through substrate vias 121. The active region 122 and the plurality of through substrate vias 121 may be considered part of the die substrate 120. The plurality of through substrate vias 121 may include plated through holes. The active region 122 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 122 of the die substrate 120.

The die substrate 120 may include silicon (Si). The die substrate 120 may comprise a bulk silicon. The bulk silicon may include a monolithic silicon. The plurality of through substrate vias 121 may extend through the die substrate 120. Different implementations may have different thicknesses for the die substrate 120.

The die interconnection 104 includes at least one dielectric layer 140 and at least one die metallization layer (e.g., die metal 0, die metal 1) with a plurality of die interconnects 142. The die interconnection 104 is coupled to the die substrate base 102. The plurality of die interconnects 142 is coupled to the active region 122 of the die substrate base 102. The plurality of die interconnects 142 may be coupled to the plurality of through substrate vias 121. The die interconnection 104 may also include a plurality of pad interconnects 101 and a passivation layer 106. In some implementations, a back end of line (BEOL) process may be used to fabricate the die interconnection 104. The die interconnection 104 may be a BEOL die interconnection. The die interconnection 104 may be an on-die interconnection.

The integrated device 100 includes a passivation layer 106, a plurality of pad interconnects 101, a plurality of metallization interconnects 103, a plurality of metallization interconnects 105, a plurality of metallization interconnects 107, a plurality of under bump metallization interconnects 109, a plurality of solder interconnects 110, an encapsulation layer 112 and a solder resist layer 108 . . . . The passivation layer 106 may be provided on the die interconnection 104. The plurality of solder interconnects 110 may be a plurality of solder bumps (e.g., solder bump interconnects).

The plurality of pad interconnects 101 may include a pad interconnect 101a, a pad interconnect 101b, a pad interconnect 101c and a pad interconnect 101d. The plurality of metallization interconnects 103 may include a metallization interconnect 103a. The plurality of metallization interconnects 105 may include a metallization interconnect 105a, a metallization interconnect 105b and a metallization interconnect 105c. The plurality of metallization interconnects 107 may include a metallization interconnect 107a and a metallization interconnect 107b. The plurality of under bump metallization interconnects 109 may include an under bump metallization interconnect 109a, an under bump metallization interconnect 109b, an under bump metallization interconnect 109c and an under bump metallization interconnect 109d. In some implementations, a back end of line (BEOL) process may be used to fabricate the passivation layer 106, the plurality of pad interconnects 101, the plurality of metallization interconnects 103, the plurality of metallization interconnects 105, the plurality of metallization interconnects 107, the plurality of under bump metallization interconnects 109, the encapsulation layer 112 and/or the solder resist layer 108.

The plurality of pad interconnects 101 may be coupled to the plurality of die interconnects 142. The plurality of pad interconnects 101 may include Aluminum (Al). The plurality of die interconnects 142 may include copper (Cu). The plurality of die interconnects 142 may include a different material from the plurality of pad interconnects 101. The passivation layer 106 may be located over the at least one dielectric layer 140. The passivation layer 106 may be coupled to and touch a top surface of the at least one dielectric layer 140. The passivation layer 106 may be located over at least part of the plurality of pad interconnects 101. The passivation layer 106 may include a material that is different from the at least one dielectric layer 140.

The metallization interconnect 103a may be coupled to and touch the pad interconnect 101a. The metallization interconnect 107a may be coupled to and touch the pad interconnect 101b and the pad interconnect 101c. The metallization interconnect 107b may be coupled to and touch the pad interconnect 101d. The plurality of metallization interconnects 103 may include copper. The plurality of metallization interconnects 107 may include copper. The plurality of metallization interconnects 103 may be located in at least one cavity of the passivation layer 106. The plurality of metallization interconnects 103 may include a via metallization interconnect, a pad metallization interconnect and/or a trace metallization interconnect. The plurality of metallization interconnects 103 may be located over a surface of the passivation layer 106. The plurality of metallization interconnects 107 may be located in at least one cavity of the passivation layer 106. The plurality of metallization interconnects 107 may include a via metallization interconnect, a pad metallization interconnect and/or a trace metallization interconnect. The plurality of metallization interconnects 107 may be located over a surface of the passivation layer 106. A thickness of a trace metallization interconnect from the plurality of metallization interconnects 107 may be greater than a thickness of a trace metallization interconnect from the plurality of metallization interconnects 103. A thickness of a metallization pad interconnect from the plurality of metallization interconnects 107 may be greater than a thickness of a metallization pad interconnect from the plurality of metallization interconnects 103. A thickness of a metallization pad interconnect (e.g., formed by a metallization interconnect 103 and a metallization interconnect 105) may be greater than a thickness of a trace metallization interconnect (e.g., formed by a metallization interconnect 103). A thickness of a metallization trace interconnect (e.g., formed by a metallization interconnect 103) may be less than a thickness of a pad metallization interconnect (e.g., formed by a metallization interconnect 103 and a metallization interconnect 105). The metallization interconnect 107a includes a first pad metallization interconnect 107a-1, a second pad metallization interconnect 107a-2 and a trace metallization interconnect 107a-3. The first pad metallization interconnect 107a-1 is coupled to the second pad metallization interconnect 107a-2 through the trace metallization interconnect 107a-3. The trace metallization interconnect 107a-3 has the same thickness as the thickness of the first pad metallization interconnect 107a-1 and/or the same thickness as the thickness of the second pad metallization interconnect 107a-2. However, in some implementations, the trace metallization interconnect 107a-3 may have a thickness that is less than the thickness of the first pad metallization interconnect 107a-1 and/or a thickness that is less than the thickness of the second pad metallization interconnect 107a-2. The first pad metallization interconnect 107a-1 vertically overlaps and/or vertically aligns with the pad interconnect 101b and the under bump metallization interconnect 109c. The second pad metallization interconnect 107a-2 vertically overlaps and/or vertically aligns with the pad interconnect 101c and the under bump metallization interconnect 109d.

The plurality of metallization interconnects 105 may be coupled to and touch the plurality of metallization interconnects 103. The metallization interconnect 105a may be coupled to and touch the metallization interconnect 103a. The metallization interconnect 105b may be coupled to and touch the metallization interconnect 103a. The metallization interconnect 105c may be coupled to and touch the metallization interconnect 103a. The plurality of metallization interconnects 105 may include copper. The plurality of metallization interconnects 105 may include a via metallization interconnect, a pad metallization interconnect and/or a trace metallization interconnect.

The encapsulation layer 112 may laterally surround at least part of the plurality of metallization interconnects 103, at least part of the plurality of metallization interconnects 105 and/or at least part of the plurality of metallization interconnects 107.

The encapsulation layer 112 may be located over the passivation layer 106. The encapsulation layer 112 may include a different material from the passivation layer 106. The encapsulation layer 112 may include a mold, a resin and/or an epoxy. The encapsulation layer 112 may be a means for encapsulation. The encapsulation layer 112 may be provided by using a compression and transfer molding process, a sheet molding process, or a liquid molding process. The encapsulation layer 112 may also be coupled to a side of the die substrate base 102 and/or the die interconnection 104. For example, the encapsulation layer 112 may be coupled to and touch a side wall of the at least one dielectric layer 140 and/or a side wall of the die substrate 120.

A solder resist layer 108 is coupled to and touch the encapsulation layer 112. At least part of the solder resist layer 108 may be located over the encapsulation layer 112. The solder resist layer 108 may include a different material from the encapsulation layer 112.

The under bump metallization interconnect 109a is coupled to and touch the metallization interconnect 105a. The under bump metallization interconnect 109b is coupled to and touch the metallization interconnect 105c. The under bump metallization interconnect 109c is coupled to and touch the metallization interconnect 107a. The under bump metallization interconnect 109d is coupled to and touch the metallization interconnect 107a. The under bump metallization interconnect 109e is coupled to and touch the metallization interconnect 107b. The plurality of under bump metallization interconnects 109 may include copper. Part of the plurality of under bump metallization interconnects 109 may be located in cavities of the solder resist layer 108. Part of the plurality of under bump metallization interconnects 109 may be located over a surface of the solder resist layer 108.

The plurality of solder interconnects 110 are coupled to and touch the plurality of under bump metallization interconnects 109. The solder interconnect 110a may be coupled to and touch the under bump metallization interconnect 109a. The solder interconnect 110b may be coupled to and touch the under bump metallization interconnect 109b. The solder interconnect 110c may be coupled to and touch the under bump metallization interconnect 109c. The solder interconnect 110d may be coupled to and touch the under bump metallization interconnect 109d. The solder interconnect 110e may be coupled to and touch the under bump metallization interconnect 109e.

In some implementations, an electrical path to and/or from an active region 122 may include at least one die interconnect from the plurality of die interconnects 142, at least one through substrate via from the plurality of through substrate vias 121. In some implementations, an electrical path to and/or from an active region 122 may include at least one die interconnect from the plurality of die interconnects 142, at least one pad interconnect from the plurality of pad interconnects 101, at least one metallization interconnect from the plurality of metallization interconnects 103, at least one metallization interconnect from the plurality of metallization interconnects 105, at least one under bump metallization interconnect from the plurality of under bump metallization interconnects 109 and/or at least one solder interconnect from the plurality of solder interconnects 110.

In some implementations, an electrical path to and/or from an active region 122 may include at least one die interconnect from the plurality of die interconnects 142, at least one through substrate via from the plurality of through substrate vias 121. In some implementations, an electrical path to and/or from an active region 122 may include at least one die interconnect from the plurality of die interconnects 142, at least one pad interconnect from the plurality of pad interconnects 101, at least one metallization interconnect from the plurality of metallization interconnects 107, at least one under bump metallization interconnect from the plurality of under bump metallization interconnects 109 and/or at least one solder interconnect from the plurality of solder interconnects 110.

In some implementations, the pad interconnect 101a, the metallization interconnect 103a, the metallization interconnect 105a, the metallization interconnect 105b, the metallization interconnect 105c, the under bump metallization interconnect 109a, the under bump metallization interconnect 109b, the solder interconnect 110a and/or the solder interconnect 110b may be part of electrical path configured for a first power.

In some implementations, the pad interconnect 101b, the pad interconnect 101c, the metallization interconnect 107a, the under bump metallization interconnect 109c, the under bump metallization interconnect 109d, the solder interconnect 110c and/or the solder interconnect 110d may be part of electrical path configured for a second power. The second power may be different from the first power.

In some implementations, the pad interconnect 101d, the metallization interconnect 107b, the under bump metallization interconnect 109e, and/or the solder interconnect 110e may be part of electrical path configured for a signal (e.g., input/output signal).

FIG. 1 illustrates that the under bump metallization interconnect 109c vertically overlaps and/or vertically aligns with the pad interconnect 101b. The under bump metallization interconnect 109d vertically overlaps and/or vertically aligns with the pad interconnect 101c. The under bump metallization interconnect 109e vertically overlaps and/or vertically aligns with the pad interconnect 101d. The metallization interconnect 107b vertically overlaps and/or vertically aligns with the under bump metallization interconnect 109e and the pad interconnect 101d. The metallization interconnect 107b includes a first pad metallization interconnect 107a-1, a second pad metallization interconnect 107a-2 and a trace metallization interconnect 107a-3. The first pad metallization interconnect 107a-1 is coupled to the second pad metallization interconnect 107a-2 through the trace metallization interconnect 107a-3. The first pad metallization interconnect 107a-1 of the metallization interconnect 107a vertically overlaps with the under bump metallization interconnect 109c and the pad interconnect 101b. The second pad metallization interconnect 107a-2 of the metallization interconnect 107a vertically overlaps with the under bump metallization interconnect 109d and the pad interconnect 101c. The trace metallization interconnect 107a-3 has the same thickness as the thickness of the first pad metallization interconnect 107a-1 and/or the same thickness as the thickness of the second pad metallization interconnect 107a-2. However, in some implementations, the trace metallization interconnect 107a-3 may have a thickness that is less than the thickness of the first pad metallization interconnect 107a-1 and/or a thickness that is less than the thickness of the second pad metallization interconnect 107a-2.

A first interconnect (e.g., first metallization interconnect) that vertically aligns with a second interconnect (e.g., second metallization interconnect) may mean that a center of the first interconnect may vertically align with a center of the second interconnect. The vertical alignment of two or more pad interconnects helps reduce and/or minimize the number of metal layers that is necessary to route electrical signals, since there is less need to fan out or redistribute interconnects in the lateral direction. Less interconnects mean less metal layers needed to accommodate the interconnects. In addition, the use of using trace metallization interconnects that are thinner helps keep pad metallization interconnects closer and thus more interconnects may be provided in a given area and/or region of the metallization portion.

FIG. 1 illustrates an example of an integrated device 100 that has a compact form factor while still providing high density interconnects. For example, the integrated device 100 may include a minimized number of metal layers above the die interconnection 104, which may reduce the overall size of the integrated device 100. For example, a hub and spoke configuration where neighboring pad interconnects may share common interconnects and/or coupled through a common interconnect, allows pad interconnects to be closer to each other, since shorting between these neighboring pad interconnects is not as much of a concern. Moreover, the integrated device 100 may be more cost effective to fabricate than other comparable integrated devices since the integrated device 100 may be fabricated by a single supplier. For example, the plurality of metallization interconnects 103, the plurality of metallization interconnects 105, the plurality of metallization interconnects 107 and/or the plurality of under bump metallization interconnects 109 may be fabricated as part of the process for fabricating the die interconnection 104, which can help reduce the overall cost of the integrated device 100.

Another advantage is that by reducing the number of metal layers for the plurality of metallization interconnects, smaller and tighter pitch may be provided for metallization interconnects and/or under bump metallization interconnects. In some implementations, the pitch for metallization interconnects and/or the pitch for under bump metallization interconnects may be in a range of about 10-40 micrometers. This may be made possible by the fact that metallization interconnects configured for power do not take up as much space (e.g., due to the use of hub and spoke configuration). Metallization interconnects and/or under bump metallization interconnects with these pitches may be configured to provide electrical paths for signals (e.g., input/output signals). The above advantage is applicable to any of the integrated device described in the disclosure.

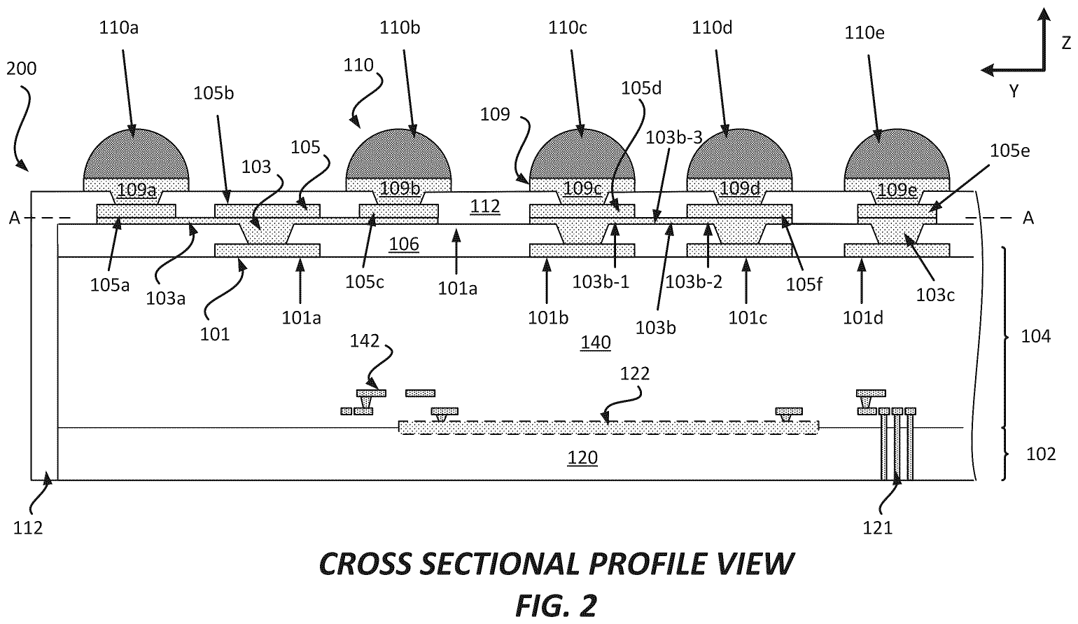

FIG. 2 illustrates an example of an integrated device 200. The integrated device 200 is similar to the integrated device 100, and may include similar components that are arranged and/or configured in a similar manner as the integrated device 100. However, the integrated device 200 may include additional components and/or components that are arranged and/or configured differently. The integrated device 200 includes a die substrate base 102 and a die interconnection 104. The die substrate base 102 includes a die substrate 120, an active region 122 and a plurality of through substrate vias 121. The active region 122 may include a plurality of logic cells, a plurality of transistors, and/or a plurality of filters. The die substrate 120 may include silicon (Si). The die substrate 120 may comprise a bulk silicon. The bulk silicon may include a monolithic silicon. The plurality of through substrate vias 121 may extend through the die substrate 120. Different implementations may have different thicknesses for the die substrate 120.

The die interconnection 104 includes at least one dielectric layer 140 and a plurality of die interconnects 142. The die interconnection 104 is coupled to the die substrate base 102. The plurality of die interconnects 142 is coupled to the active region 122 of the die substrate base 102. The plurality of die interconnects 142 may be coupled to the plurality of through substrate vias 121. The die interconnection 104 may also include a plurality of pad interconnects 101 and a passivation layer 106.

The integrated device 200 includes a plurality of metallization interconnects 103, a plurality of metallization interconnects 105, a plurality of under bump metallization interconnects 109, a plurality of solder interconnects 110, and an encapsulation layer 112.

The plurality of pad interconnects 101 may include a pad interconnect 101a, a pad interconnect 101b, a pad interconnect 101c and a pad interconnect 101d. The plurality of metallization interconnects 103 may include a metallization interconnect 103a, a metallization interconnect 103b and a metallization interconnect 103c. The plurality of metallization interconnects 105 may include a metallization interconnect 105a, a metallization interconnect 105b, a metallization interconnect 105c, a metallization interconnect 105d and a metallization interconnect 105e. The plurality of under bump metallization interconnects 109 may include an under bump metallization interconnect 109a, an under bump metallization interconnect 109b, an under bump metallization interconnect 109c, an under bump metallization interconnect 109d and an under bump metallization interconnect 109e. In some implementations, a back end of line (BEOL) process may be used to fabricate the passivation layer 106, the plurality of pad interconnects 101, the plurality of metallization interconnects 103, the plurality of metallization interconnects 105, the plurality of under bump metallization interconnects 109, and the encapsulation layer 112.

As shown in FIG. 2, the plurality of pad interconnects 101 may be coupled to the plurality of die interconnects 142. The plurality of pad interconnects 101 may include Aluminum (Al). The plurality of die interconnects 142 may include copper (Cu). The plurality of die interconnects 142 may include a different material from the plurality of pad interconnects 101. The passivation layer 106 may be located over the at least one dielectric layer 140. The passivation layer 106 may be coupled to and touch a top surface of the at least one dielectric layer 140. The passivation layer 106 may be located over at least part of the plurality of pad interconnects 101. The passivation layer 106 may include a material that is different from the at least one dielectric layer 140.

As further shown in FIG. 2, the metallization interconnect 103a may be coupled to and touch the pad interconnect 101a. The metallization interconnect 103b may be coupled to and touch the pad interconnect 101b and the pad interconnect 101c. The metallization interconnect 103c may be coupled to and touch the pad interconnect 101d. The plurality of metallization interconnects 103 may include copper.

The plurality of metallization interconnects 105 may be coupled to and touch the plurality of metallization interconnects 103. The metallization interconnect 105a may be coupled to and touch the metallization interconnect 103a. The metallization interconnect 105b may be coupled to and touch the metallization interconnect 103a. The metallization interconnect 105c may be coupled to and touch the metallization interconnect 103a. The metallization interconnect 105d may be coupled to and touch the metallization interconnect 103b. The metallization interconnect 105f may be coupled to and touch the metallization interconnect 103b. The metallization interconnect 105e may be coupled to and touch the metallization interconnect 103c. The plurality of metallization interconnects 105 may include copper. The plurality of metallization interconnects 105 may include a via metallization interconnect, a pad metallization interconnect and/or a trace metallization interconnect.

The under bump metallization interconnect 109a is coupled to and touch the metallization interconnect 105a. The under bump metallization interconnect 109b is coupled to and touch the metallization interconnect 105c. The under bump metallization interconnect 109c is coupled to and touch the metallization interconnect 105d. The under bump metallization interconnect 109d is coupled to and touch the metallization interconnect 105d. The under bump metallization interconnect 109e is coupled to and touch the metallization interconnect 105e.

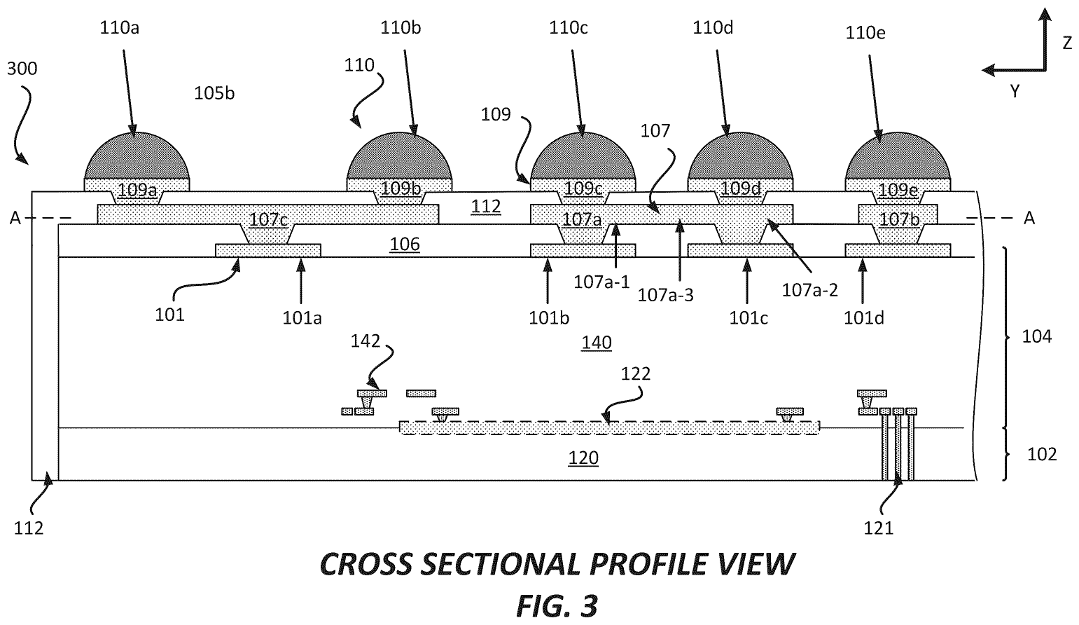

FIG. 3 illustrates that the under bump metallization interconnect 109c vertically overlaps and/or vertically aligns with the pad interconnect 101b. The under bump metallization interconnect 109d vertically overlaps and/or vertically aligns with the pad interconnect 101c. The metallization interconnect 105d (which may be a pad metallization interconnect) vertically overlaps and/or vertically aligns with the under bump metallization interconnect 109c and the pad interconnect 101b. The metallization interconnect 105f (which may be a pad metallization interconnect) vertically overlaps and/or vertically aligns with the under bump metallization interconnect 109d and the pad interconnect 101c. The metallization interconnect 105d is coupled to the metallization interconnect 105f through the metallization interconnect 103b. The thickness of a trace metallization interconnect 103b-3 of the metallization interconnect 103b may be less than the combined thickness of the metallization interconnect 105d and a first pad metallization interconnect 103b-1 of the metallization interconnect 103b. The thickness of the trace metallization interconnect 103b-3 of the metallization interconnect 103b may be less than the combined thickness of the metallization interconnect 105f and a second pad metallization interconnect 103b-2 of the metallization interconnect 103b.

The plurality of solder interconnects 110 are coupled to and touch the plurality of under bump metallization interconnects 109. The solder interconnect 110a may be coupled to and touch the under bump metallization interconnect 109a. The solder interconnect 110b may be coupled to and touch the under bump metallization interconnect 109b. The solder interconnect 110c may be coupled to and touch the under bump metallization interconnect 109c. The solder interconnect 110d may be coupled to and touch the under bump metallization interconnect 109d. The solder interconnect 110e may be coupled to and touch the under bump metallization interconnect 109e.

FIG. 3 illustrates an example of an integrated device 300. The integrated device 300 is similar to the integrated device 100, and may include similar components that are arranged and/or configured in a similar manner as the integrated device 100. However, the integrated device 300 may include additional components and/or components that are arranged and/or configured differently. The integrated device 300 includes a die substrate base 102 and a die interconnection 104. The die substrate base 102 includes a die substrate 120, an active region 122 and a plurality of through substrate vias 121. The active region 122 may include a plurality of logic cells, a plurality of transistors, and/or a plurality of filters. The die substrate 120 may include silicon (Si). The die substrate 120 may comprise a bulk silicon. The bulk silicon may include a monolith silicon. The plurality of through substrate vias 121 may extend through the die substrate 120. Different implementations may have different thicknesses for the die substrate 120.

The die interconnection 104 includes at least one dielectric layer 140 and a plurality of die interconnects 142. The die interconnection 104 is coupled to the die substrate base 102. The plurality of die interconnects 142 is coupled to the active region 122 of the die substrate base 102. The plurality of die interconnects 142 may be coupled to the plurality of through substrate vias 121. The die interconnection 104 may also include a plurality of pad interconnects 101 and a passivation layer 106.

The integrated device 300 includes a plurality of metallization interconnects 107, a plurality of under bump metallization interconnects 109, a plurality of solder interconnects 110, and an encapsulation layer 112. The plurality of pad interconnects 101 includes a pad interconnect 101a, a pad interconnect 101b, a pad interconnect 101c, and a pad interconnect 101d. The plurality of metallization interconnects 107 includes a metallization interconnect 107a, a metallization interconnect 107b and a metallization interconnect 107c. The plurality of under bump metallization interconnects 109 includes an under bump metallization interconnect 109a, an under bump metallization interconnect 109b, an under bump metallization interconnect 109c, an under bump metallization interconnect 109d and an under bump metallization interconnect 109e.

As shown in FIG. 3, the metallization interconnect 107c is coupled to and touch the pad interconnect 101a. The metallization interconnect 107a is coupled to and touch the pad interconnect 101b and the pad interconnect 101c. The metallization interconnect 107b is coupled to and touch the pad interconnect 101d. The under bump metallization interconnect 109a may be coupled to and touch the metallization interconnect 107c. The under bump metallization interconnect 109b may be coupled to and touch the metallization interconnect 107c. The under bump metallization interconnect 109c may be coupled to and touch the metallization interconnect 107a. The under bump metallization interconnect 109d may be coupled to and touch the metallization interconnect 107a. The under bump metallization interconnect 109e may be coupled to and touch the metallization interconnect 107b.

As further shown in FIG. 3, the solder interconnect 110a may be coupled to and touch the under bump metallization interconnect 109a. The solder interconnect 110b may be coupled to and touch the under bump metallization interconnect 109b. The solder interconnect 110c may be coupled to and touch the under bump metallization interconnect 109c. The solder interconnect 110d may be coupled to and touch the under bump metallization interconnect 109d. The solder interconnect 110e may be coupled to and touch the under bump metallization interconnect 109e.

In some implementations, some metallization interconnects from the plurality of metallization interconnects 103, some metallization interconnects from the plurality of metallization interconnects 105, and/or some metallization interconnects from the plurality of metallization interconnects 107, of the integrated device 100, the integrated device 200 and/or the integrated device 300, may be located vertically over portions of the encapsulation layer 112 that is located to the side of the die interconnection 104 and located to the side of the die substrate base 102. Thus, some metallization interconnects from the plurality of metallization interconnects 103, some metallization interconnects from the plurality of metallization interconnects 105, and/or some metallization interconnects from the plurality of metallization interconnects 107 may not vertically overlap with the die substrate base 102 and the die interconnection 104.

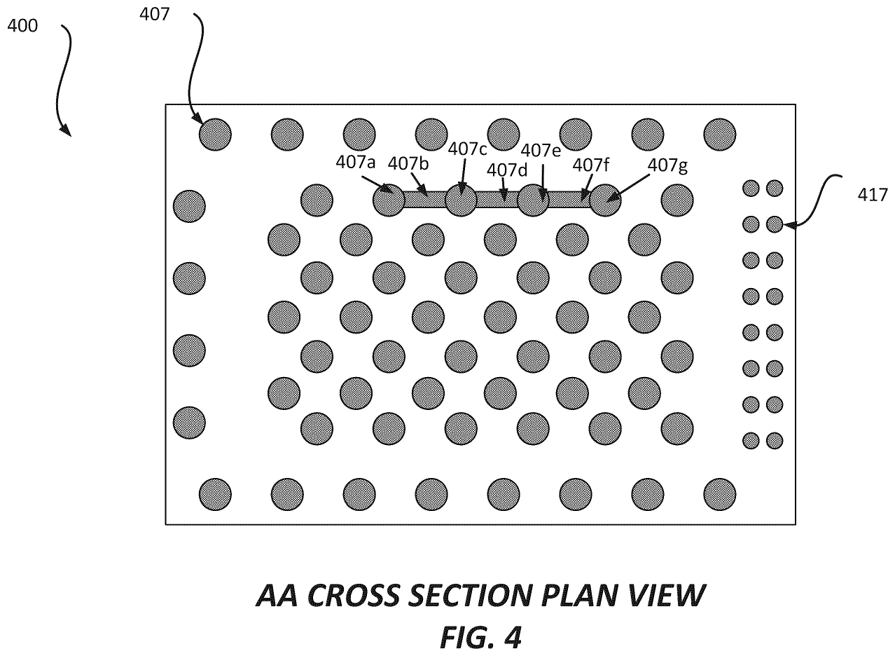

FIG. 4 illustrates an exemplary plan view of a cross section of the integrated device 400. The integrated device 400 may illustrate a representation of the integrated device 100, the integrated device 200, the integrated device 300 and/or any of the integrated devices described in the disclosure. For example, the integrated device 400 may be an illustration of the AA cross section of the integrated device 300.

The integrated device 400 includes a plurality of metallization interconnects 407 and a plurality of metallization interconnects 417. In some implementations, the plurality of metallization interconnects 407 and/or the plurality of metallization interconnects 417 may represent the plurality of metallization interconnects 107 of the integrated device 300. The plurality of metallization interconnects 407 may include a metallization interconnect 407a, a metallization interconnect 407b, a metallization interconnect 407c, a metallization interconnect 407d, a metallization interconnect 407e, a metallization interconnect 407f, and a metallization interconnect 407g.

The plurality of metallization interconnects 407 may be configured to provide one or more electrical paths for one or more power. The plurality of metallization interconnects 417 may be configured to provide electrical paths for signals (e.g., input/output signals). The plurality of metallization interconnects 417 may have smaller minimum dimensions from the plurality of metallization interconnects 407. For example, the plurality of metallization interconnects 417 may have a minimum pitch that is less than the minimum pitch of the plurality of metallization interconnects 407.

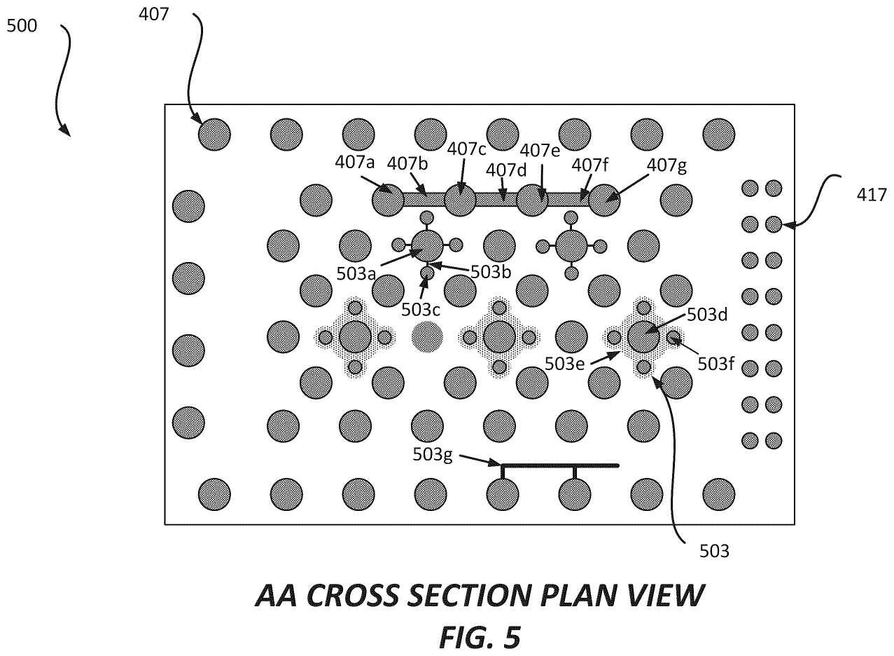

FIG. 5 illustrates an exemplary plan view of a cross section of the integrated device 500. The integrated device 500 may illustrate a representation of the integrated device 100, the integrated device 200, the integrated device 300 and/or any of the integrated devices described in the disclosure. For example, the integrated device 500 may be an illustration of the AA cross section of the integrated device 100.

The integrated device 500 includes a plurality of metallization interconnects 407, a plurality of metallization interconnects 417 and a plurality of metallization interconnects 503. In some implementations, the plurality of metallization interconnects 407 and/or the plurality of metallization interconnects 417 may represent the plurality of metallization interconnects 107 of the integrated device 100. The plurality of metallization interconnects 407 may include a metallization interconnect 407a, a metallization interconnect 407b, a metallization interconnect 407c, a metallization interconnect 407d, a metallization interconnect 407e, a metallization interconnect 407f, and a metallization interconnect 407g.

In some implementations, the plurality of metallization interconnects 503 may represent the plurality of metallization interconnects 103 and/or the plurality of metallization interconnects 105 of the integrated device 100. The plurality of metallization interconnects 503 may include a metallization interconnect 503a, a metallization interconnect 503b, a metallization interconnect 503c, a metallization interconnect 503d, a metallization interconnect 503e, a metallization interconnect 503f, and a metallization interconnect 503g.

Some of the interconnects from the plurality of metallization interconnects 503 may be arranged in a hub and spoke configuration. For example, the metallization interconnect 503a, the metallization interconnect 503b and the metallization interconnect 503c may be part of metallization interconnects that are arranged in a first hub and spoke configuration. The metallization interconnect 503b may be coupled to the metallization interconnect 503a and the metallization interconnect 503c. The metallization interconnect 503a may be a hub for the first hub and a spoke configuration. The metallization interconnect 503c may be a spoke for the first hub and spoke configuration. The width of the metallization interconnect 503a may be greater than the width of the metallization interconnect 503c. The first hub and spoke configuration may include a plurality of spokes. The first hub and spoke configuration may be configured to provide an electrical path for a first power.

Different hub and spoke configurations may have different configurations. The metallization interconnect 503d, the metallization interconnect 503e and the metallization interconnect 503f may be part of metallization interconnects that are arranged in a second hub and spoke configuration. The metallization interconnect 503e may be coupled to the metallization interconnect 503d and the metallization interconnect 503f. The metallization interconnect 503d may be a hub for the second hub and a spoke configuration. The metallization interconnect 503f may be a spoke for the second hub and spoke configuration. The second hub and spoke configuration may include a plurality of spokes. The second hub and spoke configuration may be configured to provide an electrical path for a second power. The second power may be different from the first power. In some implementations, the first power may have a first voltage and the second power may have a second voltage that is different from the first voltage.

The different arrangements of the plurality of metallization interconnects 407 and/or the plurality of metallization interconnects 503 may help provide a more effective power distribution network for the integrated device. For example, the plurality of metallization interconnects 407 and/or the plurality of metallization interconnects 503 may be arranged to efficiently provide the proper amount of power to various components of the integrated device 500.

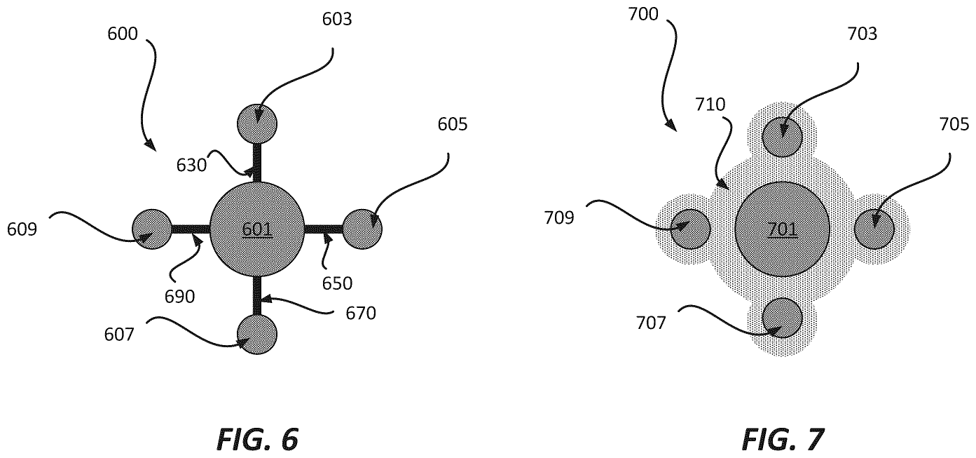

FIGS. 6 and 7 illustrates various examples of a hub and spoke configuration. FIG. 6 illustrates a hub and spoke configuration 600 that includes an interconnect 601, an interconnect 603, an interconnect 605, an interconnect 607, an interconnect 609, an interconnect 630, an interconnect 650, an interconnect 670 and an interconnect 690. One or more of these interconnects may be metallization interconnects (e.g., 103, 105, 107). The interconnect 601 may be hub interconnect. The interconnect 603, the interconnect 605, the interconnect 607 and the interconnect 609 may each be spoke interconnects. The interconnect 601, the interconnect 603, the interconnect 605, the interconnect 607 and the interconnect 609 may each be a pad interconnect. The interconnect 630 may be coupled to the interconnect 601 and the interconnect 603. The interconnect 650 may be coupled to the interconnect 601 and the interconnect 605. The interconnect 670 may be coupled to the interconnect 601 and the interconnect 607. The interconnect 690 may be coupled to the interconnect 601 and the interconnect 609. The hub and spoke configuration 600 may include a different number of spokes. The hub and spoke configuration 600 may be implemented in the integrated device 100, the integrated device 200 and/or the integrated device 300.

FIG. 7 illustrates a hub and spoke configuration 700 that includes an interconnect 701, an interconnect 703, an interconnect 705, an interconnect 707, an interconnect 709 and an interconnect 710. One or more of these interconnects may be metallization interconnects (e.g., 103, 105, 107). The interconnect 701 may be hub interconnect. The interconnect 703, the interconnect 705, the interconnect 707 and the interconnect 709 may each be spoke interconnects. The interconnect 701, the interconnect 703, the interconnect 705, the interconnect 707 and the interconnect 709 may each be a pad interconnect. The interconnect 710 may be coupled to the interconnect 701, the interconnect 703, the interconnect 705, the interconnect 707, and the interconnect 709. The hub and spoke configuration 700 may include a different number of spokes. The hu and spoke configuration 700 may be implemented in the integrated device 100, the integrated device 200 and/or the integrated device 300.

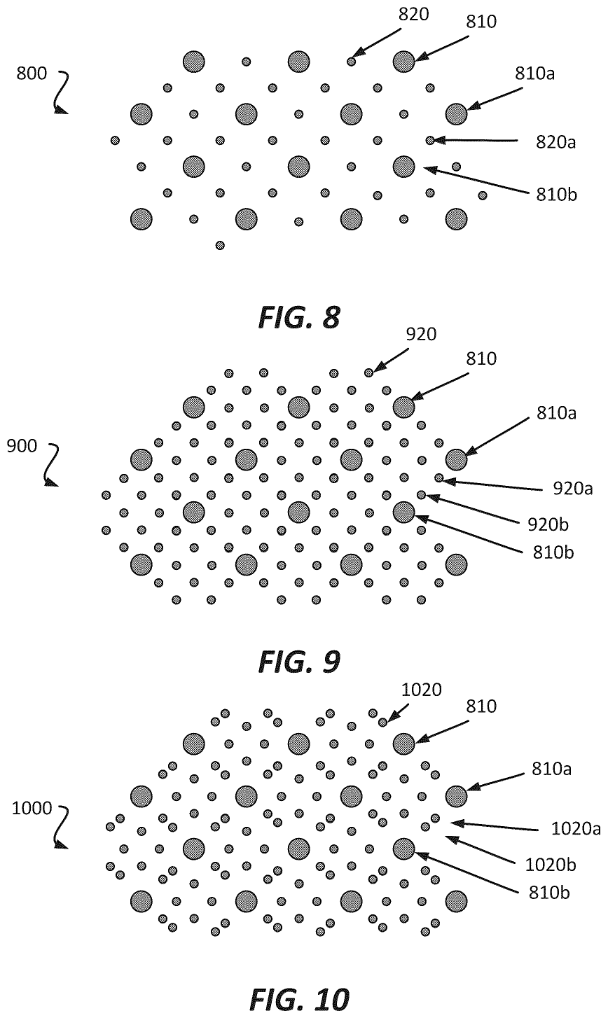

FIGS. 8-10 illustrate various examples of arrangements of pad interconnects for an integrated devices. The arrangements shown in FIGS. 8-10 may be implemented in any of the integrated devices described in the disclosure.

FIG. 8 illustrates a configuration 800 that includes a plurality of metallization interconnects 810 (e.g., large pad interconnects) and a plurality of metallization interconnects 820 (e.g., small pad interconnects). The plurality of metallization interconnects 820 have smaller widths than the plurality of metallization interconnects 810. The metallization interconnect 820a is located between the metallization interconnect 810a and the metallization interconnect 810b. The configuration 800 illustrates there is one small pad interconnect between two large pad interconnects. The configuration 800 illustrates that the pitches for the plurality of metallization interconnects 820 is smaller than the pitches for the plurality of metallization interconnects 810.

FIG. 9 illustrates a configuration 900 that includes a plurality of metallization interconnects 810 (e.g., large pad interconnects) and a plurality of metallization interconnects 920 (e.g., small pad interconnects). The plurality of metallization interconnects 920 have smaller widths than the plurality of metallization interconnects 810. The metallization interconnect 920a and the metallization interconnect 920b are located between the metallization interconnect 810a and the metallization interconnect 810b. The configuration 900 illustrates there are two small pad interconnects between two large pad interconnects. The configuration 900 illustrates that the pitches for the plurality of metallization interconnects 920 is smaller than the pitches for the plurality of metallization interconnects 810.

FIG. 10 illustrates a configuration 1000 that includes a plurality of metallization interconnects 810 (e.g., large pad interconnects) and a plurality of metallization interconnects 1020 (e.g., small pad interconnects). The plurality of metallization interconnects 1020 have smaller widths than the plurality of metallization interconnects 810. The metallization interconnect 1020a and the metallization interconnect 1020b are located between the metallization interconnect 810a and the metallization interconnect 810b. The configuration 1000 illustrates there are two small pad interconnects between two large pad interconnects. However, the spacing between metallization interconnects from the plurality of metallization interconnects 1020 may vary. The configuration 1000 illustrates that the pitches for the plurality of metallization interconnects 1020 is smaller than the pitches for the plurality of metallization interconnects 810.

In some implementations, the plurality of metallization interconnects 810 may be configured as landing spots for probe during a testing of the integrated device and/or a wafer that includes the integrated devices. In some implementations, one or more of the metallization interconnects from the plurality of metallization interconnects 810 may be dummy metallization interconnects and/or redundant metallization interconnects. The larger pads may be necessary due to the size of the probes, would not be able to touch and/or properly align with the smaller sizes of the plurality of metallization interconnects 820, the plurality of metallization interconnects 920 and/or the plurality of metallization interconnects 1020. For example, a probe may touch the metallization interconnect 810a to test signals or provide power to the integrated device. The metallization interconnect 810 may be coupled to the metallization interconnect 820a, which may be used as a landing pad for solder interconnects when the integrated device is coupled to another integrated device, a substrate or a board. The combination of using larger pads and small pads allows for a compact form factor for the integrated device, while providing metallization interconnects with small pitches, while at the same time providing large enough pad that a probe can touch during the testing of the wafer and/or the integrated device. In some implementations, the plurality of metallization interconnects 820, the plurality of metallization interconnects 920 and/or the plurality of metallization interconnects 1020 may be configured to provide electrical paths (i) between the integrated device and another integrated device, (ii) between the integrated device and a substrate (e.g., interposer), and/or (iii) between the integrated device and a board.

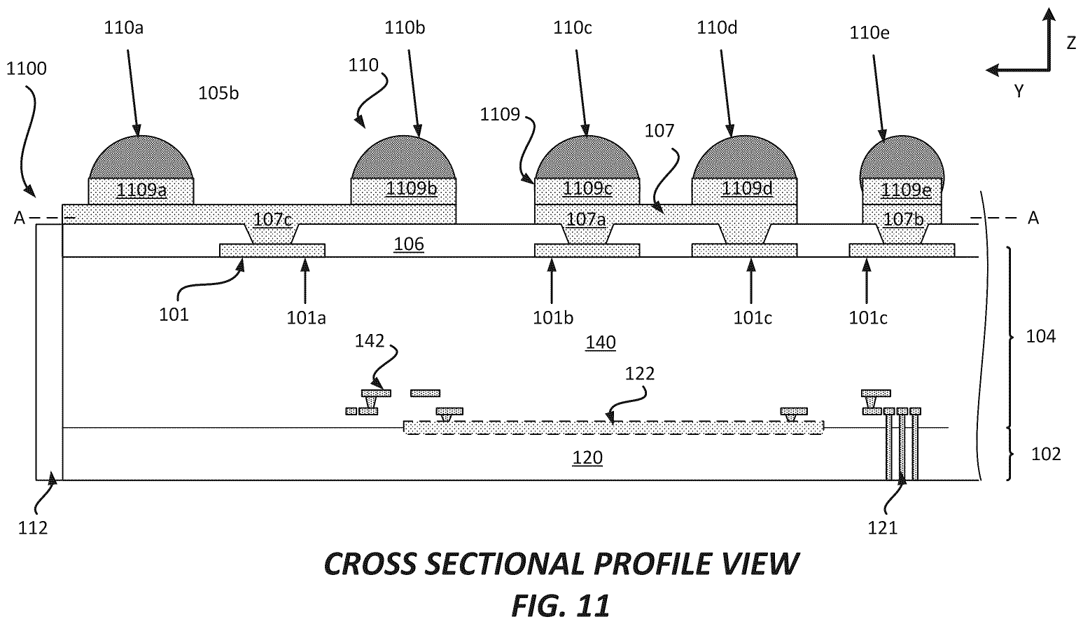

FIG. 11 illustrates an example of an integrated device 1100. The integrated device 1100 is similar to the integrated device 300, and may include similar components that are arranged and/or configured in a similar manner as the integrated device 300. However, the integrated device 1100 may include additional components and/or components that are arranged and/or configured differently. For example, in FIG. 11 the encapsulation layer 112 is located on the side of the integrated device 1100. However, in FIG. 3, the encapsulation layer 112 may be located on the side of the integrated device 300 and on a top surface of the integrated device 300. The integrated device 1100 includes a die substrate base 102 and a die interconnection 104. The die substrate base 102 includes a die substrate 120, an active region 122 and a plurality of through substrate vias 121. The active region 122 may include a plurality of logic cells, a plurality of transistors, and/or a plurality of filters. The die substrate 120 may include silicon (Si). The die substrate 120 may comprise a bulk silicon. The bulk silicon may include a monolith silicon. The plurality of through substrate vias 121 may extend through the die substrate 120. Different implementations may have different thicknesses for the die substrate 120.

The die interconnection 104 includes at least one dielectric layer 140 and a plurality of die interconnects 142. The die interconnection 104 is coupled to the die substrate base 102. The plurality of die interconnects 142 is coupled to the active region 122 of the die substrate base 102. The plurality of die interconnects 142 may be coupled to the plurality of through substrate vias 121. The die interconnection 104 may also include a plurality of pad interconnects 101 and a passivation layer 106.

The integrated device 1100 includes a plurality of metallization interconnects 107, a plurality of metallization interconnects 1109, a plurality of solder interconnects 110, and an encapsulation layer 112. The plurality of pad interconnects 101 includes a pad interconnect 101a, a pad interconnect 101b, a pad interconnect 101c, and a pad interconnect 101d. The plurality of metallization interconnects 107 includes a metallization interconnect 107a, a metallization interconnect 107b and a metallization interconnect 107c. The plurality of metallization interconnects 1109 includes a metallization interconnect 1109a, a metallization interconnect 1109b, a metallization interconnect 1109c, a metallization interconnect 1109d, and a metallization interconnect 1109e.

As shown in FIG. 11, the metallization interconnect 107c is coupled to and touch the pad interconnect 101a. The metallization interconnect 107a is coupled to and touch the pad interconnect 101b and the pad interconnect 101c. The metallization interconnect 107b is coupled to and touch the pad interconnect 101d. The metallization interconnect 1109a may be coupled to and touch the metallization interconnect 107c. The metallization interconnect 1109b may be coupled to and touch the metallization interconnect 107c. The metallization interconnect 1109c may be coupled to and touch the metallization interconnect 107a. The metallization interconnect 1109d may be coupled to and touch the metallization interconnect 107a. The metallization interconnect 1109e may be coupled to and touch the metallization interconnect 107b.

As further shown in FIG. 11, the solder interconnect 110a may be coupled to and touch the metallization interconnect 1109a. The solder interconnect 110b may be coupled to and touch the metallization interconnect 1109b. The solder interconnect 110c may be coupled to and touch the metallization interconnect 1109c. The solder interconnect 110d may be coupled to and touch the metallization interconnect 1109d. The solder interconnect 110e may be coupled to and touch the metallization interconnect 1109e.

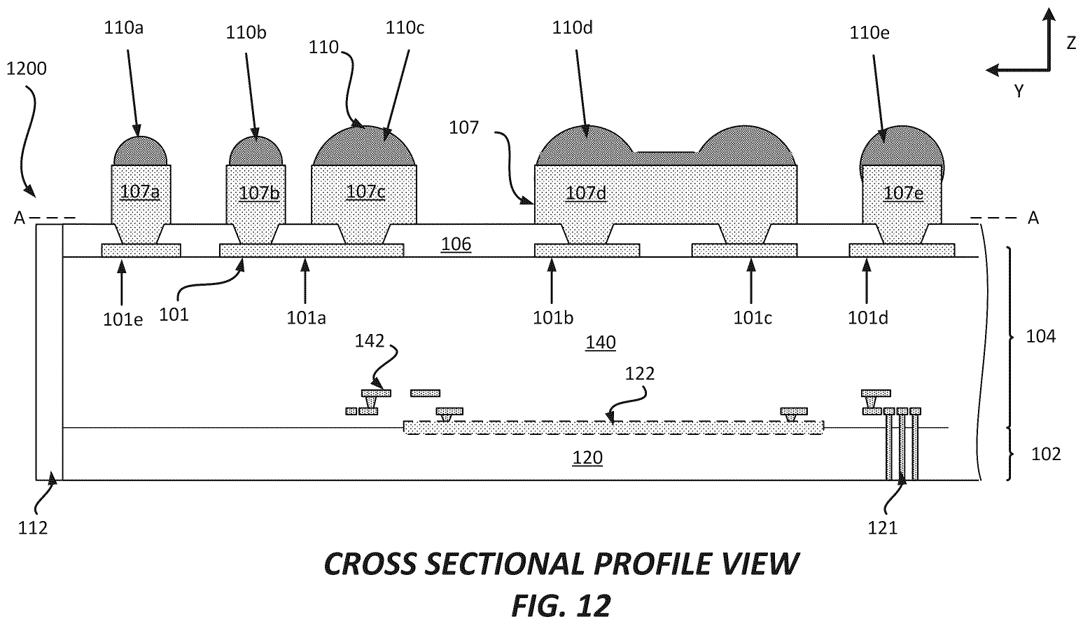

FIG. 12 illustrates an example of an integrated device 1200. The integrated device 1200 is similar to the integrated device 300, and may include similar components that are arranged and/or configured in a similar manner as the integrated device 300. However, the integrated device 300 may include additional components and/or components that are arranged and/or configured differently. For example, the thicker metallization interconnect 107 help provide higher aspect ratios interconnects, which may help provide more space between the integrated device 1200 and another integrated device and/or another component. The integrated device 1200 includes a die substrate base 102 and a die interconnection 104. The die substrate base 102 includes a die substrate 120, an active region 122 and a plurality of through substrate vias 121. The active region 122 may include a plurality of logic cells, a plurality of transistors, and/or a plurality of filters. The die substrate 120 may include silicon (Si). The die substrate 120 may comprise a bulk silicon. The bulk silicon may include a monolith silicon. The plurality of through substrate vias 121 may extend through the die substrate 120. Different implementations may have different thicknesses for the die substrate 120.

The die interconnection 104 includes at least one dielectric layer 140 and a plurality of die interconnects 142. The die interconnection 104 is coupled to the die substrate base 102. The plurality of die interconnects 142 is coupled to the active region 122 of the die substrate base 102. The plurality of die interconnects 142 may be coupled to the plurality of through substrate vias 121. The die interconnection 104 may also include a plurality of pad interconnects 101 and a passivation layer 106.

The integrated device 1200 includes a plurality of metallization interconnects 107, a plurality of solder interconnects 110, and an encapsulation layer 112. The plurality of pad interconnects 101 includes a pad interconnect 101a, a pad interconnect 101b, a pad interconnect 101c, a pad interconnect 101d and a pad interconnect 101e. The plurality of metallization interconnects 107 includes a metallization interconnect 107a, a metallization interconnect 107b, a metallization interconnect 107c, a metallization interconnect 107d and a metallization interconnect 107e.

As shown in FIG. 12, the metallization interconnect 107a is coupled to and touch the pad interconnect 101e. The metallization interconnect 107b is coupled to and touch the pad interconnect 101a. The metallization interconnect 107c is coupled to and touch the pad interconnect 101a. The metallization interconnect 107d is coupled to and touch the pad interconnect 101b and the pad interconnect 101c. The metallization interconnect 107e is coupled to and touch the pad interconnect 101d. The plurality of metallization interconnects 107 may have configured as post metallization interconnects that have a thickness or height that is substantially greater than the thickness of the plurality of pad interconnects 101.

As further shown in FIG. 12, the solder interconnect 110a may be coupled to and touch the metallization interconnect 107a. The solder interconnect 110b may be coupled to and touch the metallization interconnect 107b. The solder interconnect 110c may be coupled to and touch the metallization interconnect 107c. The solder interconnect 110d may be coupled to and touch the metallization interconnect 107d. The solder interconnect 110e may be coupled to and touch the metallization interconnect 107e.

An integrated device (e.g., 100) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advance technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

It is noted that different implementations may use solder interconnects with different materials, shapes and/or sizes. For example, one or more solder interconnects from the plurality of solder interconnects 110 may have a dome shape. In some implementations, one or more solder interconnects from the plurality of solder interconnects 110 may have one or more flat surfaces (e.g., top flat surface, bottom flat surface). Similarly, different implementations may use pad interconnects with different materials, shapes and/or sizes. For example, one or more pad interconnects may include aluminum (Al), copper (Cu), nickel (Ni), gold (Au) and/or platinum (Pt). Any of the interconnects from the plurality of pad interconnects, the plurality of metallization interconnects and/or the plurality of interconnects may include one or more layers of different materials. In some implementations, the plurality of pad interconnects and the plurality of interconnects may form continuous interconnects and/or contiguous interconnects

It is noted that the configurations of the plurality of metallization interconnects (e.g., 103), the plurality of metallization interconnects (e.g., 105), the plurality of metallization interconnects (e.g., 107), the plurality of under bump metallization interconnects (e.g., 109) are not limited to an integrated device. In some implementations, the above metallization interconnects may be implemented as part of a passive device (e.g., die passive device), an interposer (e.g., passive silicon interposer), metallization portion interposer, re-built wafer (e.g., reconstituted wafer) and/or metallization portion on a re-built wafer.

### Exemplary Sequence for Fabricating an Integrated Device

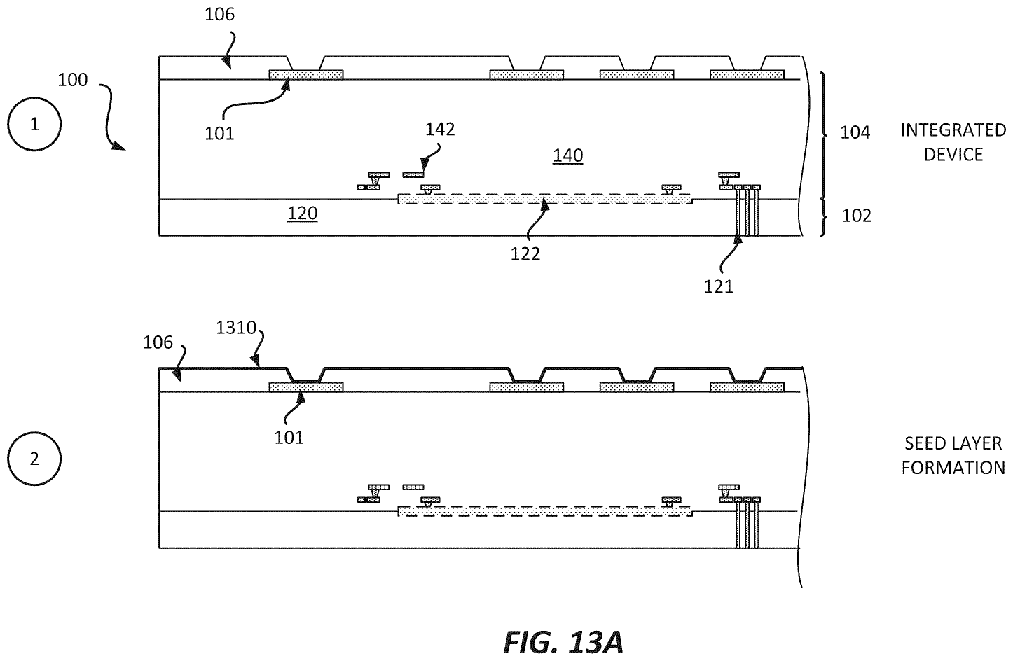

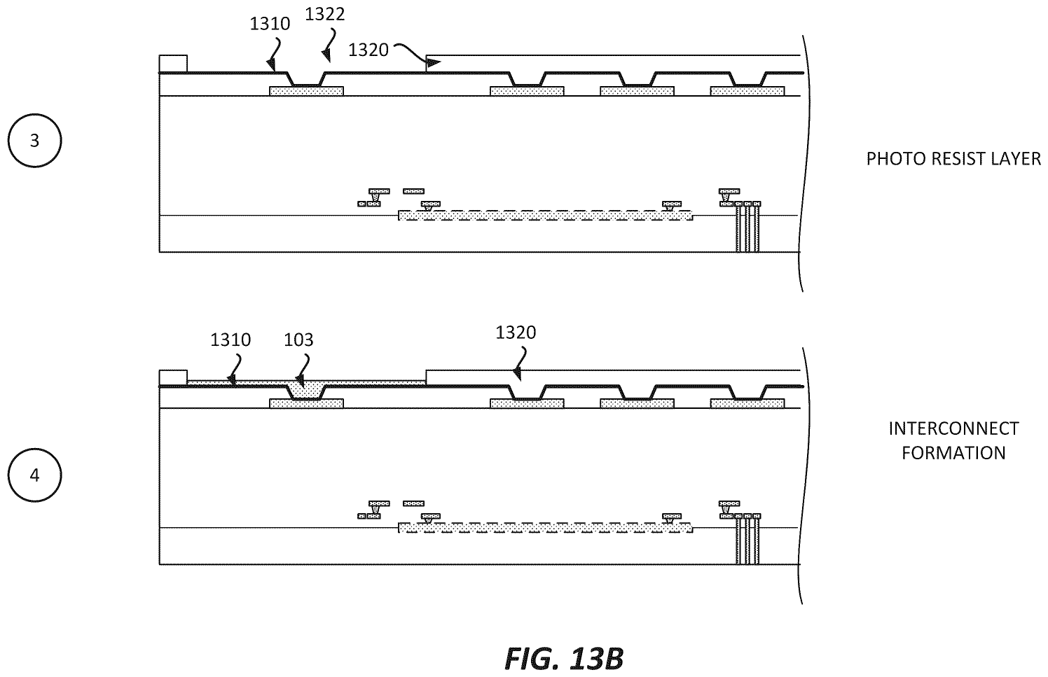

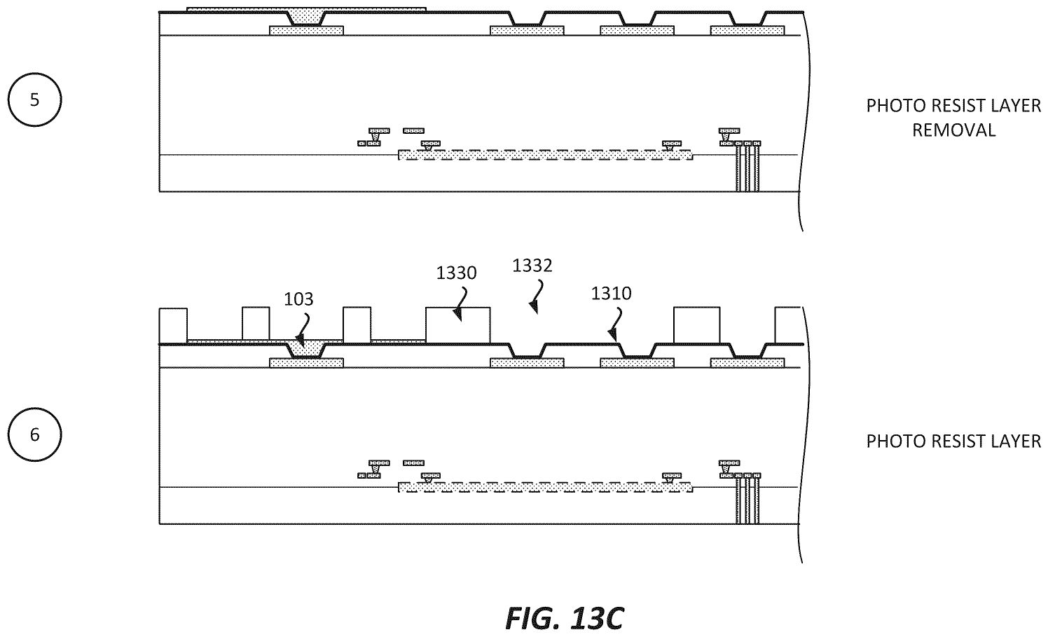

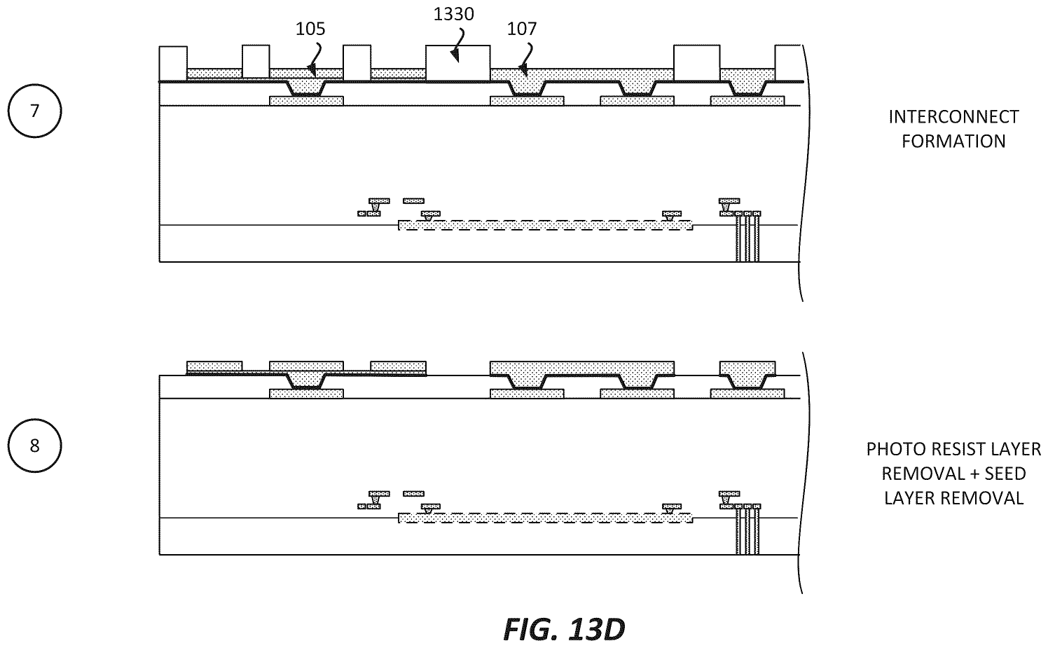

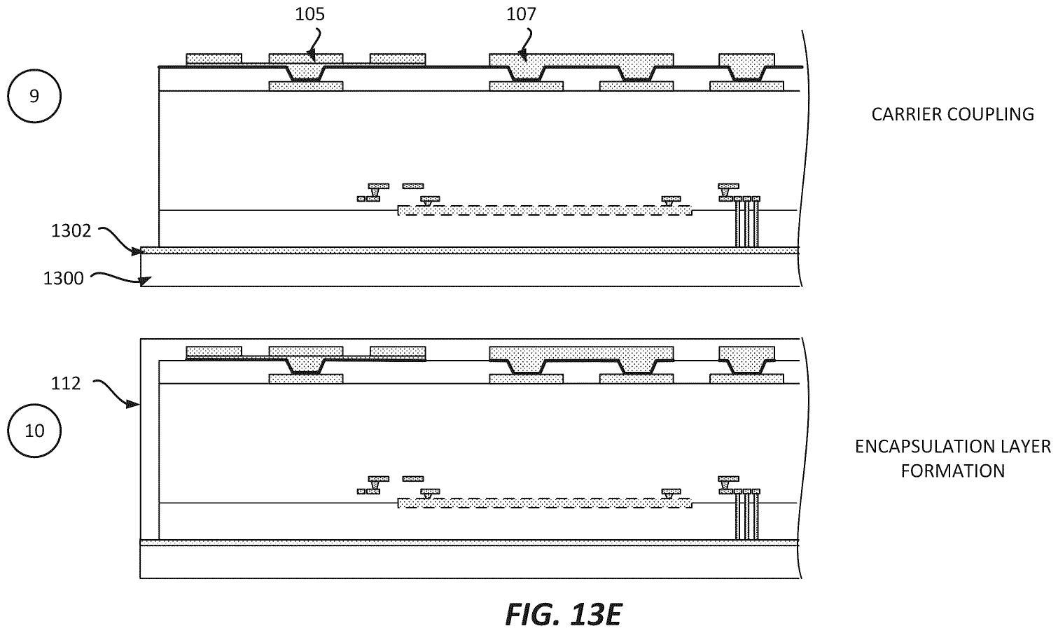

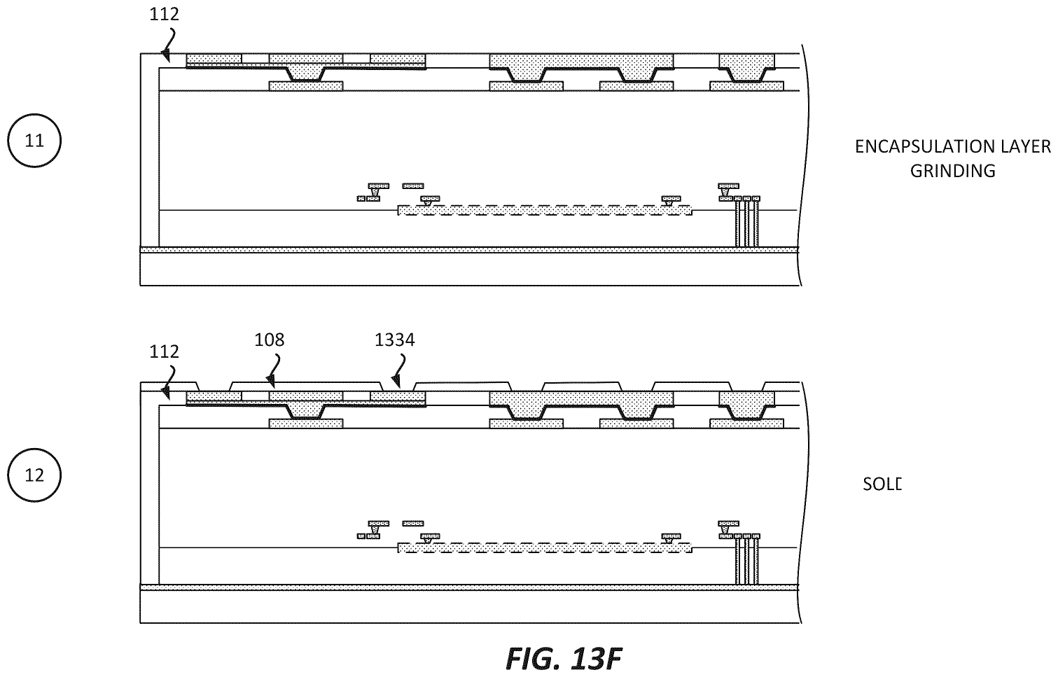

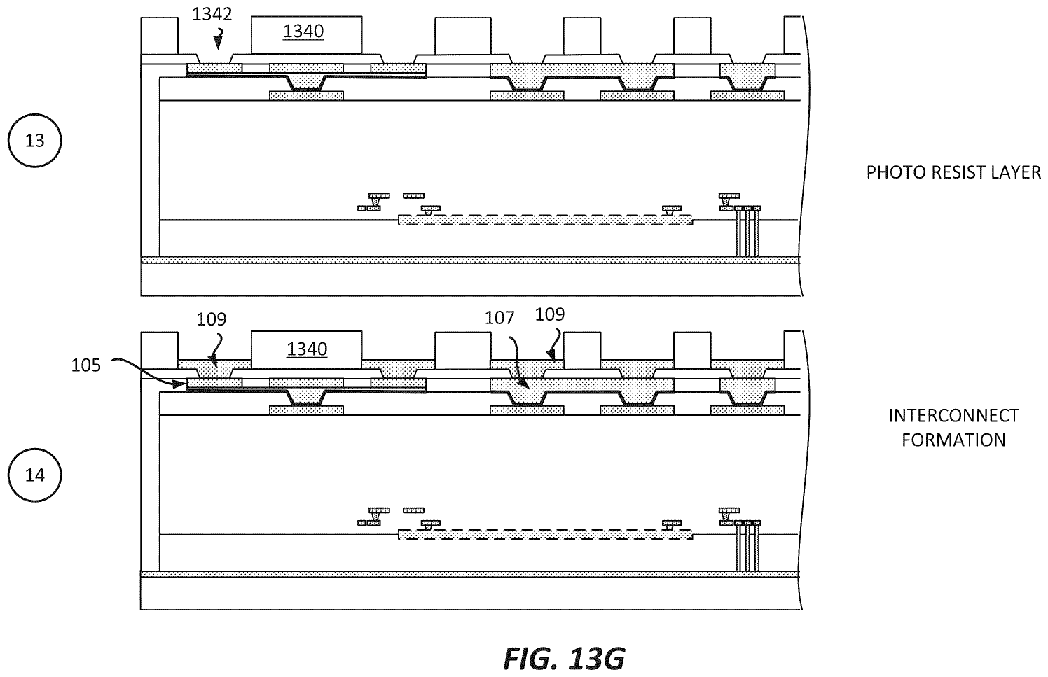

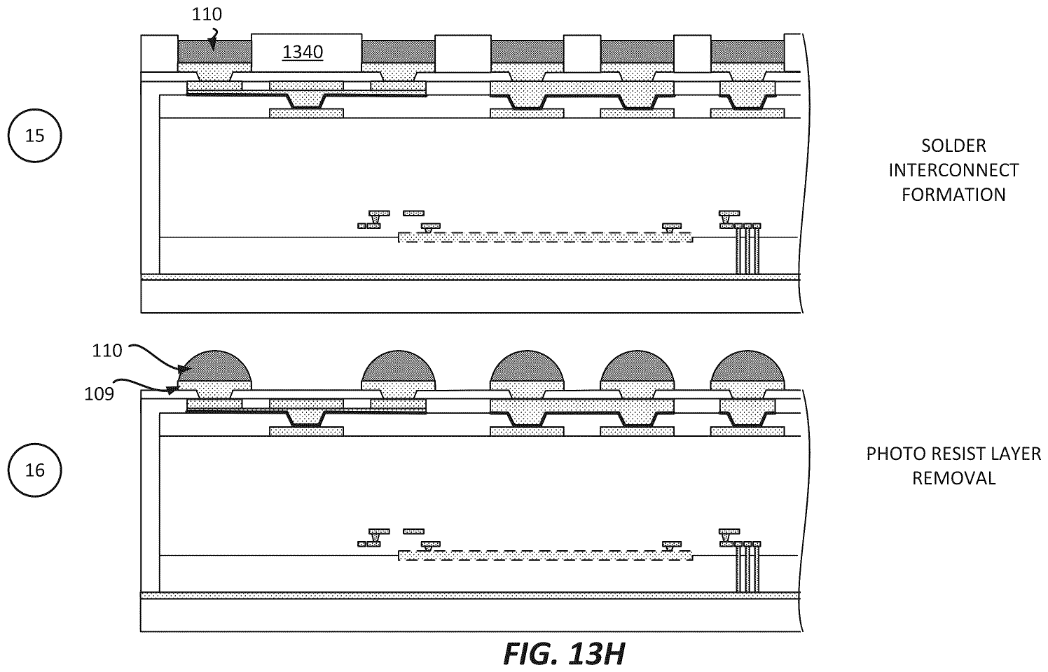

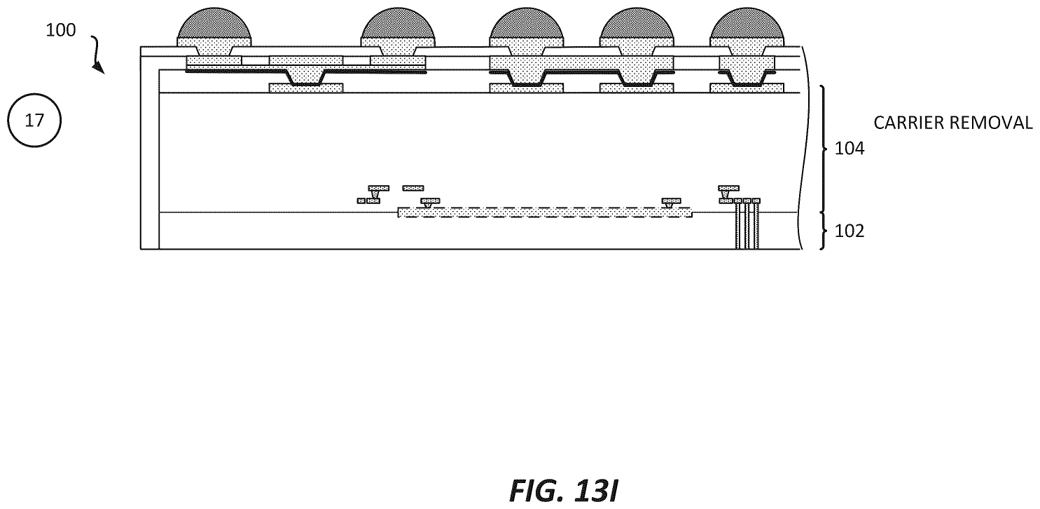

In some implementations, fabricating an integrated device includes several processes. FIGS. 13A-13I illustrate an exemplary sequence for providing or fabricating an integrated device. In some implementations, the sequence of FIGS. 13A-13I may be used to provide or fabricate the integrated device 100. However, the process of FIGS. 13A-13I may be used to fabricate any of the integrated devices described in the disclosure.

It should be noted that the sequence of FIGS. 13A-13I may combine one or more stages in order to simplify and/or clarify the sequence for providing or fabricating an integrated device. In some implementations, the order of the processes may be changed or modified. In some implementations, one or more of processes may be replaced or substituted without departing from the scope of the disclosure.

Stage 1, as shown in FIG. 13A, illustrates a state after an integrated device is provided and/or fabricated. The integrated device 100 may include a die substrate base 102. The die substrate base 102 may include a die substrate 120, a die interconnection 104 (e.g., die interconnection portion), a passivation layer 106, and a plurality of metallization interconnects 107. The integrated device 100 may include a bare die (e.g., semiconductor bare die). Thus, in some implementations, a bare die that includes a die substrate 120, a die interconnection 104 (e.g., die interconnection portion, on-die interconnection), at least one passivation layer (e.g., 106) and a plurality of metallization interconnects 107, may be provided at stage 1. In some implementations, the integrated device 100 is provided and/or fabricated as part of a wafer. As will be further described below, an integrated device may include additional components and/or other components, which may be fabricated onto the integrated device that is provided at stage 1.

Stage 2 illustrates a state after a seed layer 1310 is formed. The seed layer 1310 may include copper. The seed layer 1310 may be formed over a surface of the passivation layer 106. The seed layer 1310 may also be formed over the plurality of pad interconnects 101. A plating process may be used to form the seed layer 1310.

Stage 3, as shown in FIG. 13B, illustrates a state after a photo resist layer 1320 is formed over the seed layer 1310. The photo resist layer 1320 may include openings 1322. A deposition process, a lamination process, an exposure process and/or a development process may be used to form the photo resist layer 1320.

Stage 4 illustrates a state after a plurality of metallization interconnects 103 are formed. The plurality of metallization interconnects 103 may be formed and coupled to the seed layer 1310. The plurality of metallization interconnects 103 may be formed through the openings 1322 of the photo resist layer 1320. A plating process may be used to form the plurality of metallization interconnects 103.

Stage 5, as shown in FIG. 13C, illustrates a state after the photo resist layer 1320 is removed. A stripping process may be used to remove the photo resist layer 1320.

Stage 6 illustrates a state after a photo resist layer 1330 is formed over the seed layer 1310 and/or the plurality of metallization interconnects 103. The photo resist layer 1330 may include openings 1332. A deposition process, a lamination process, an exposure process and/or a development process may be used to form the photo resist layer 1330.

Stage 7, as shown in FIG. 13D, illustrates a state after a plurality of metallization interconnects 105 and a plurality of metallization interconnects 107 are formed. The plurality of metallization interconnects 105 may be formed and coupled to the plurality of metallization interconnects 103. The plurality of metallization interconnects 107 may be formed and coupled to the seed layer 1310. The plurality of metallization interconnects 105 and/or the plurality of metallization interconnects 107 may be formed through the openings 1332 of the photo resist layer 1330. A plating process may be used to form the plurality of metallization interconnects 105 and/or the plurality of metallization interconnects 107.

Stage 8 illustrates a state after the photo resist layer 1330 is removed. A stripping process may be used to remove the photo resist layer 1330.

Stage 9, as shown in FIG. 13E, illustrates a state after the integrated device 100 is placed and coupled to a carrier 1300 through an adhesive 1302.

Stage 10 illustrates a state after an encapsulation layer 112 is formed and coupled to the integrated device 100. The encapsulation layer 112 may be coupled to a side surface and/or a side wall of the integrated device 100. The encapsulation layer 112 may touch a side surface of the passivation layer 106, a side surface of the dielectric layer 140 and/or a side surface of the die substrate 120. The encapsulation layer 112 may be formed over the passivation layer 106. The encapsulation layer 112 may include a mold, a resin and/or an epoxy. A compression molding process, a transfer molding process, or a liquid molding process may be used to form the encapsulation layer 112.

Stage 11, as shown in FIG. 13F, after portions of the encapsulation layer 112 may be removed. For example, a top portion of the encapsulation layer 112 may be grinded off.

Stage 12, illustrates a state after a solder resist layer 108 is formed over the encapsulation layer 112. The solder resist layer 108 may include openings 1334. A deposition process, a lamination process, an exposure process and/or a development process may be used to form the solder resist layer 108.

Stage 13, as shown in FIG. 13G, illustrates a state after a photo resist layer 1340 is formed over the solder resist layer 108. The photo resist layer 1340 may include openings 1342. A deposition process, a lamination process, an exposure process and/or a development process may be used to form the photo resist layer 1340.

Stage 14 illustrates a state after a plurality of under bump metallization interconnects 109 are formed. The plurality of under bump metallization interconnects 109 may be formed and coupled to the plurality of metallization interconnects 105 and/or the plurality of metallization interconnects 107. The plurality of under bump metallization interconnects 109 may be formed through the openings 1342 of the photo resist layer 1340. A plating process may be used to form the plurality of under bump metallization interconnects 109.

Stage 15, as shown in FIG. 13H illustrates a state after a plurality of solder interconnects 110 are formed and coupled to the plurality of under bump metallization interconnects 109. A pasting process may be used to form the plurality of solder interconnects 110 through the openings 1342 of the photo resist layer 1340. A solder reflow process may be used to couple the plurality of solder interconnects 110 to the plurality of under bump metallization interconnects 109.

Stage 16 illustrates a state after the photo resist layer 1340 is removed. A stripping process may be used to remove the photo resist layer 1340.

Stage 17, as shown in FIG. 13I, illustrates after the integrated device 100 is decoupled from the carrier 1300. The adhesive 1302 and the carrier 1300 may be detached from the integrated device 100.

### Exemplary Flow Diagram of a Method for Fabricating an Integrated Device

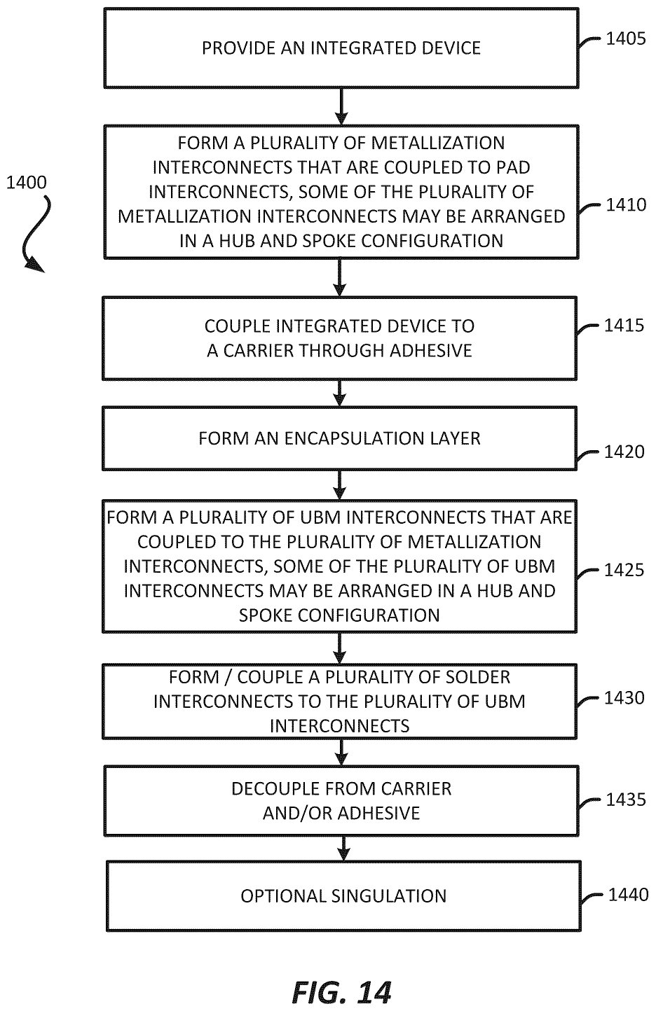

In some implementations, fabricating an integrated device includes several processes. FIG. 14 illustrates an exemplary flow diagram of a method 1400 for providing or fabricating an integrated device. In some implementations, the method 1400 of FIG. 14 may be used to provide or fabricate the integrated device 100 of FIG. 1 described in the disclosure. However, the method 1400 may be used to provide or fabricate any of the integrated devices described in the disclosure.

It should be noted that the method 1400 of FIG. 14 may combine one or more processes in order to simplify and/or clarify the method for providing or fabricating an integrated device. In some implementations, the order of the processes may be changed or modified.

The method provides (at 1405) an integrated device that includes a die substrate, a die interconnection and a plurality of pad interconnects, and couples the integrated device to a carrier through an adhesive. Stage 1 of FIG. 13A, illustrates and describes an example of a state after an integrated device is provided and/or fabricated. The integrated device 100 may include a die substrate base 102. The die substrate base 102 may include a die substrate 120, a die interconnection 104 (e.g., interconnection portion), a passivation layer 106, a plurality of metallization interconnects 107. The integrated device 100 may include a bare die (e.g., semiconductor bare die). Thus, in some implementations, a bare die that includes a die substrate 120, a die interconnection 104 (e.g., die interconnection portion), at least one passivation layer (e.g., 106) and a plurality of metallization interconnects 107, may be provided at stage 1. In some implementations, the integrated device 100 is provided and/or fabricated as part of a wafer. As will be further described below, an integrated device may include additional components and/or other components, which may be fabricated onto the integrated device that is provided at stage 1.

The method forms (at 1410) a plurality of metallization interconnects coupled to the plurality of pad interconnects. Some of the metallization interconnects may be arranged in a hub and spoke configuration. Stage 2 of FIG. 13A through stage 8 of FIG. 13D, illustrates and describes an example of forming a plurality of metallization interconnects.

Stage 2 of FIG. 13A, illustrates and describes an example of a state after a seed layer 1310 is formed. The seed layer 1310 may include copper. The seed layer 1310 may be formed over a surface of the passivation layer 106. The seed layer 1310 may also be formed over the plurality of pad interconnects 101. A plating process may be used to form the seed layer 1310.

Stage 3 of FIG. 13B, illustrates and describes an example of a state after a photo resist layer 1320 is formed over the seed layer 1310. The photo resist layer 1320 may include openings 1322. A deposition process, a lamination process, an exposure process and/or a development process may be used to form the photo resist layer 1320.

Stage 4 of FIG. 13B, illustrates and describes an example of a state after a plurality of metallization interconnects 103 are formed. The plurality of metallization interconnects 103 may be formed and coupled to the seed layer 1310. The plurality of metallization interconnects 103 may be formed through the openings 1322 of the photo resist layer 1320. A plating process may be used to form the plurality of metallization interconnects 103. The seed layer 1310 may be considered part of the plurality of metallization interconnects 103.

Stage 5 of FIG. 13C, illustrates and describes an example of a state after the photo resist layer 1320 is removed. A stripping process may be used to remove the photo resist layer 1320.

Stage 6 of FIG. 13C, illustrates and describes an example of a state after a photo resist layer 1330 is formed over the seed layer 1310 and/or the plurality of metallization interconnects 103. The photo resist layer 1330 may include openings 1332. A deposition process, a lamination process, an exposure process and/or a development process may be used to form the photo resist layer 1330.

Stage 7 of FIG. 13D, illustrates and describes an example of a state after a plurality of metallization interconnects 105 and a plurality of metallization interconnects 107 are formed. The plurality of metallization interconnects 105 may be formed and coupled to the plurality of metallization interconnects 103. The plurality of metallization interconnects 107 may be formed and coupled to the seed layer 1310. The plurality of metallization interconnects 105 and/or the plurality of metallization interconnects 107 may be formed through the openings 1332 of the photo resist layer 1330. A plating process may be used to form the plurality of metallization interconnects 105 and/or the plurality of metallization interconnects 107.

Stage 8 of FIG. 13D, illustrates and describes an example of a state after the photo resist layer 1330 is removed. A stripping process may be used to remove the photo resist layer 1330.

The method couples (at 1415) the integrated device to a carrier through an adhesive. Stage 9 of FIG. 13E, illustrates and describes an example of a state after the integrated device 100 is placed and coupled to a carrier 1300 through an adhesive.

The method forms and couples (at 1420) an encapsulation layer to a side surface of the integrated device. Stage 10 of FIG. 13E, illustrates and describes an example of a state after an encapsulation layer 112 is formed and coupled to the integrated device 100. The encapsulation layer 112 may be coupled to a side surface and/or a side wall of the integrated device 100. The encapsulation layer 112 may touch a side surface of the passivation layer 106, a side surface of the dielectric layer 140 and/or a side surface of the die substrate 120. The encapsulation layer 112 may be formed over the passivation layer 106. The encapsulation layer 112 may touch a top surface of the passivation layer 106. The encapsulation layer 112 may include a mold, a resin and/or an epoxy. A compression molding process, a transfer molding process, or a liquid molding process may be used to form the encapsulation layer 112.

The method may also remove (at 1420) portions of the encapsulation layer 112. Removing portions of the encapsulation layer may include grinding off a top portion of the encapsulation layer 112. Stage 11 of FIG. 13F, illustrates and describes an example removing portions of an encapsulation layer.

In some implementations, once the encapsulation layer is formed, a solder resist layer may be formed. Stage 12 of FIG. 13F, illustrates and describes an example of a state after a solder resist layer 108 is formed over the encapsulation layer 112. The solder resist layer 108 may include openings 1334. A deposition process, a lamination process, an exposure process and/or a development process may be used to form the solder resist layer 108.

Th method forms (at 1425) a plurality of under bump metallization interconnects that are coupled to the plurality of metallization interconnects. Some of the under bump metallization interconnects may be arranged in a hub and spoke configuration. Stage 13 of FIG. 13G through stage 14 of FIG. 13G illustrate an example of forming a plurality of under bump metallization interconnects. Stage 13 of FIG. 13G, illustrates and describes an example of a state after a photo resist layer 1340 is formed over the solder resist layer 108. The photo resist layer 1340 may include openings 1342. A deposition process, a lamination process, an exposure process and/or a development process may be used to form the photo resist layer 1340.

Stage 14 of FIG. 13G, illustrates and describes an example of a state after a plurality of under bump metallization interconnects 109 are formed. The plurality of under bump metallization interconnects 109 may be formed and coupled to the plurality of metallization interconnects 105 and/or the plurality of metallization interconnects 107. The plurality of under bump metallization interconnects 109 may be formed through the openings 1342 of the photo resist layer 1340. A plating process may be used to form the plurality of under bump metallization interconnects 109.

The method forms and couples (at 1430) a plurality of solder interconnects to the plurality of under bump metallization interconnects. Stage 15 of FIG. 13H, illustrates and describes an example of a state after a plurality of solder interconnects 110 are formed and coupled to the plurality of under bump metallization interconnects 109. A pasting process may be used to form the plurality of solder interconnects 110 through the openings 1342 of the photo resist layer 1340. A solder reflow process may be used to couple the plurality of solder interconnects 110 to the plurality of under bump metallization interconnects 109.

Stage 16 of FIG. 13H, illustrates and describes an example of a state after the photo resist layer 1340 is removed. A stripping process may be used to remove the photo resist layer 1340.

The method decouples (at 1435) the carrier and the adhesive from the integrated device. Stage 17 of FIG. 13I, illustrates and describes an example of after the integrated device 100 is decoupled from the carrier 1300. The adhesive 1302 and the carrier 1300 may be detached from the integrated device 100.

In some implementations, the integrated device may be one or many integrated device on a wafer. In such instances, the method may singulate (at 1440) wafer to form individual integrated devices.

### Exemplary Package and Integrated Devices

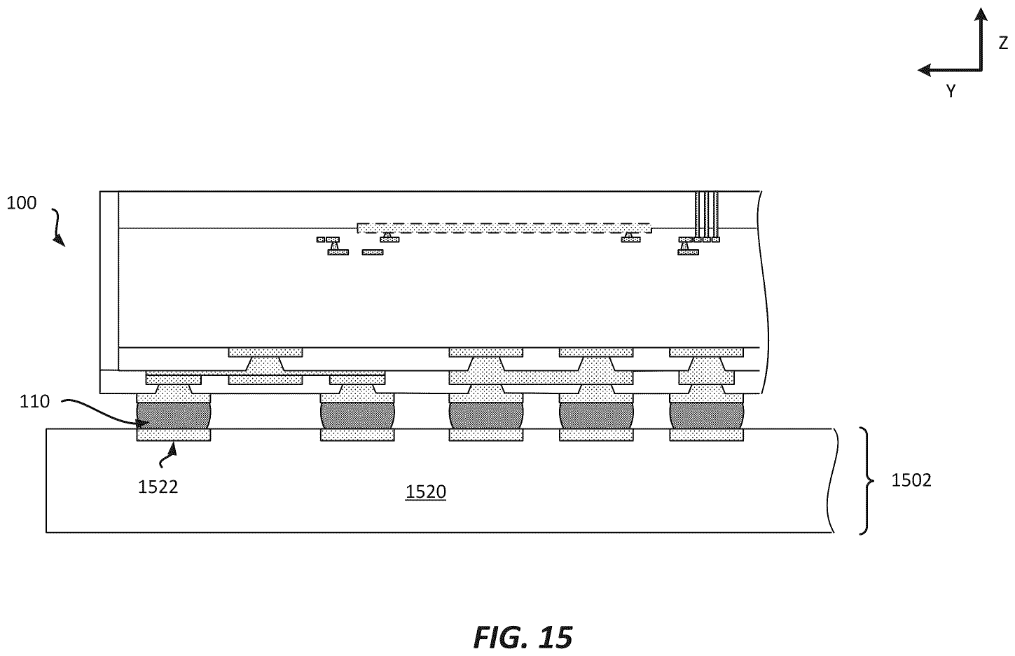

FIG. 15 illustrates a cross sectional profile view of an integrated device 100 that is coupled to a board 1502. The integrated device 100 may be coupled to the board 1502 through the plurality of solder interconnects 110. The board 1502 may include a printed circuit board (PCB). The board 1502 may include a board dielectric layer 1520 and a plurality of board interconnects 1522. Any of the integrated devices described in the disclosure may be coupled to the board. For example the integrated device 200 and/or the integrated device 300 may be coupled to the board 1502 through a plurality of solder interconnects.

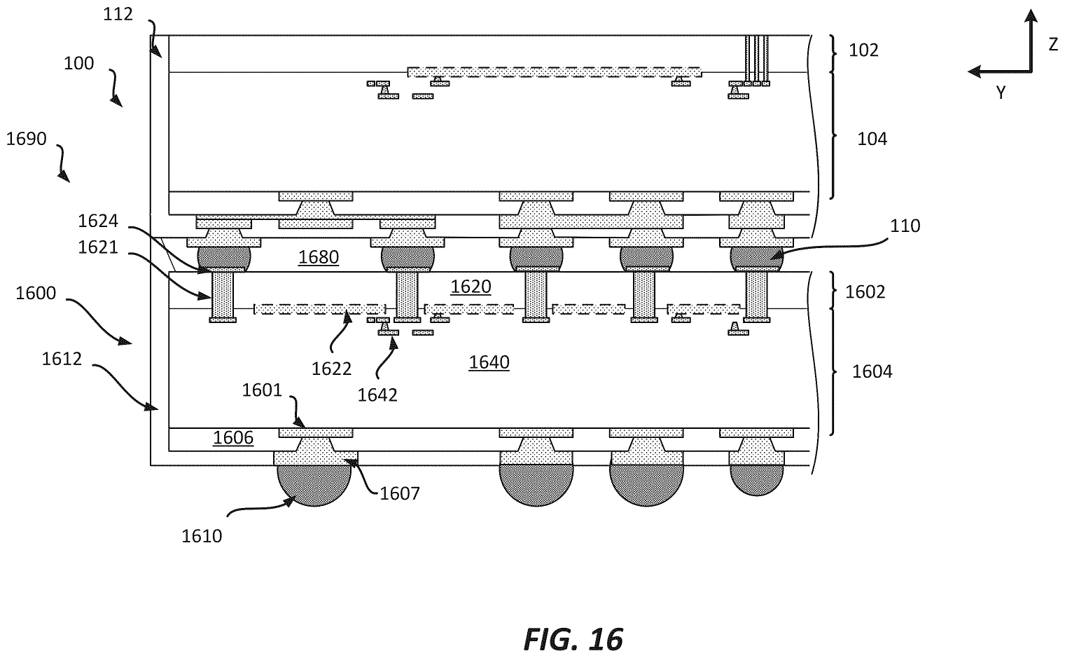

FIG. 16 illustrates a cross section profile view of a package 1690 that includes two integrated devices. The package 1690 includes the integrated device 100 and an integrated device 1600. The integrated device 1600 may be similar to the integrated device 100.

The integrated device 1600 includes a die substrate base 1602 and a die interconnection 1604. The die substrate base 1602 includes a die substrate 1620, an active region 1622 and a plurality of through substrate vias 1621. The active region 1622 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 1622 of the die substrate 1620.

The die interconnection 1604 includes at least one dielectric layer 1640 and a plurality of die interconnects 1642. The die interconnection 1604 is coupled to the die substrate base 1602. The plurality of die interconnects 1642 is coupled to the active region 1622 of the die substrate base 1602. The plurality of die interconnects 1642 may be coupled to the plurality of through substrate vias 1621. The die interconnection 1604 may also include a plurality of pad interconnects 1601 and a passivation layer 1606. In some implementations, a back end of line (BEOL) process may be used to fabricate the die interconnection 1604. The integrated device 1600 also includes an encapsulation layer 1612, a plurality of metallization interconnects 1607, and a plurality of solder interconnects 1610. The integrated device 1600 includes a plurality of back side metallization interconnects 1624 that are coupled to the plurality of through substrate vias 1621.

The integrated device 100 is coupled to the integrated device 1600 through the plurality of solder interconnects 110. The front side of the integrated device 100 may be closest to the back side of the integrated device 1600. The front side of the integrated device 100 may be coupled to the back side of the integrated device 1600 through the plurality of solder interconnects 110. The plurality of solder interconnects 110 may be coupled to the metallization interconnects and/or under bump metallization interconnects of the integrated device 100. The plurality of solder interconnects 110 may be coupled to the plurality of back side metallization interconnects 1624 and/or the plurality of through substrate vias 1621 of the integrated device 1600. An underfill 1680 may be located between the integrated device 100 and the integrated device 1600. In some implementations, the package 1690 may be coupled to the board 1502 through the plurality of solder interconnects 1610.

It is noted that a package may include any combination of the integrated devices (e.g., 100, 200, 300, 1610) described in the disclosure.

### Exemplary Sequence for Fabricating a Package Comprising Integrated Devices

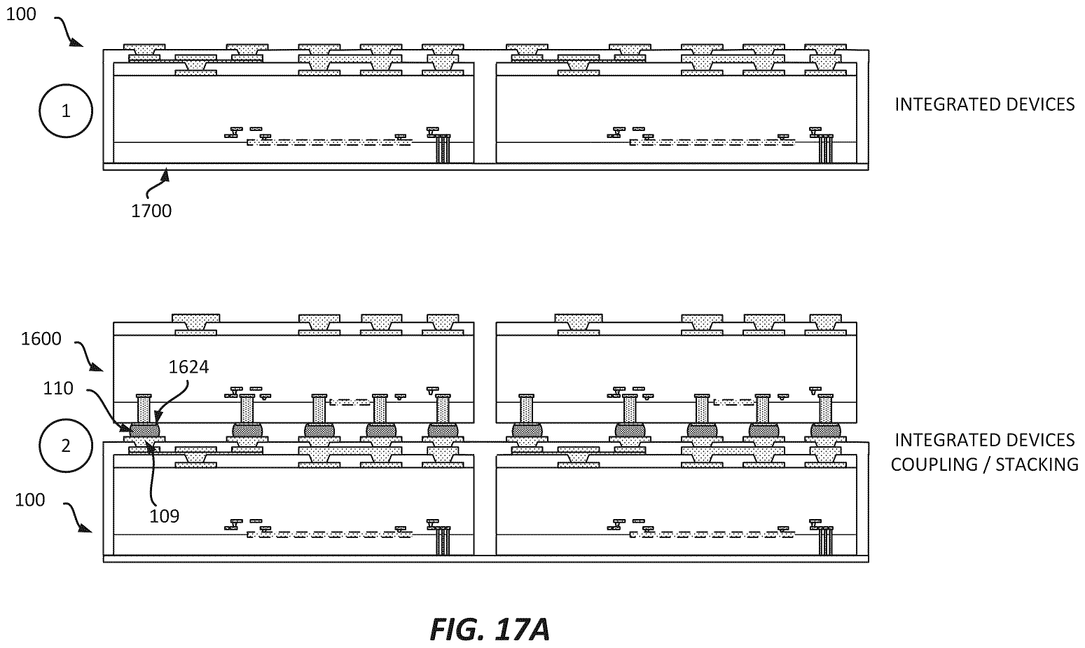

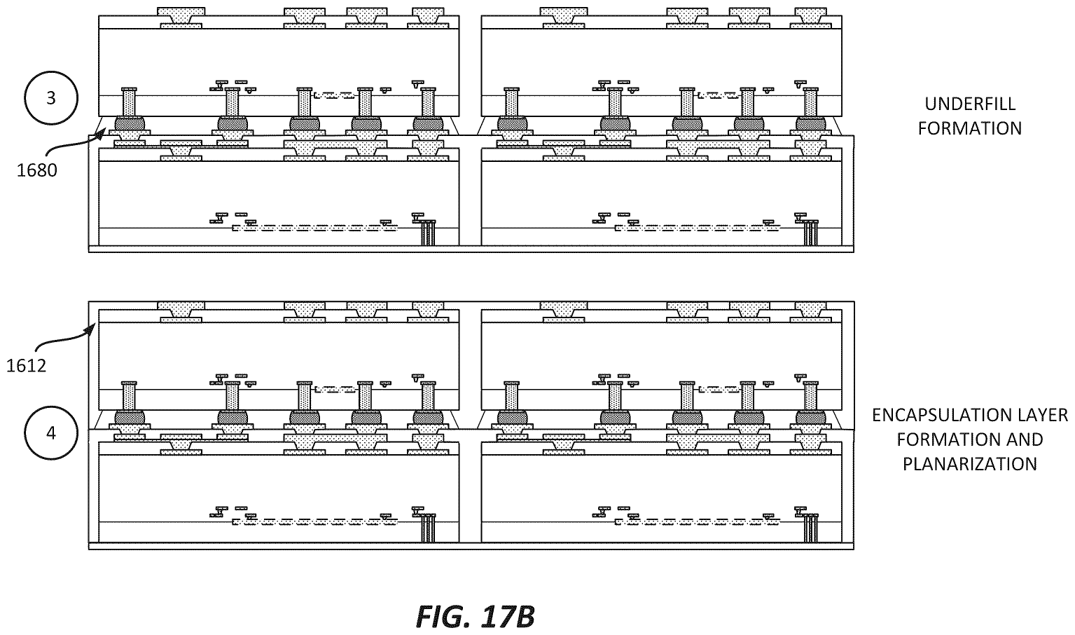

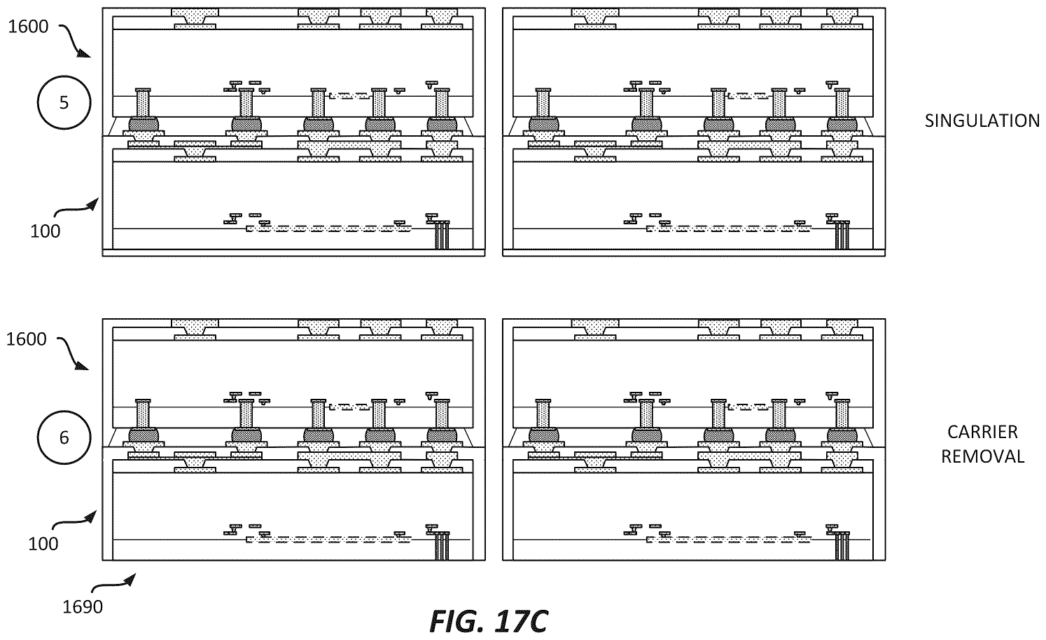

In some implementations, fabricating a package includes several processes. FIGS. 17A-17C illustrate an exemplary sequence for providing or fabricating a package that includes integrated devices. In some implementations, the sequence of FIGS. 17A-17C may be used to provide or fabricate the package 1690 of FIG. 16. However, the process of FIGS. 17A-17C may be used to fabricate any of the packages described in the disclosure.

It should be noted that the sequence of FIGS. 17A-17C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 17A illustrates a state after several integrated devices (e.g., first integrated devices, 100) are provided and coupled to a carrier 1700. An adhesive may be used to couple the integrated device to the carrier. The several integrated devices may be uncut integrated devices that are part of a wafer.

Stage 2 illustrates a state after several integrated devices (e.g., second integrated devices, 1600) are coupled to the first integrated devices (e.g., 100) through a plurality of solder interconnects (e.g., 110). A solder reflow process may be used to couple the integrated device 1600 (e.g., second integrated device) to the integrated device 100 (e.g. first integrated device). The plurality of solder interconnects 110 may be coupled to (i) the plurality of back side metallization interconnects 1624 of the integrated device 1600 and (ii) the plurality of under bump metallization interconnects 109 of the integrated device 100.

Stage 3, as shown in FIG. 17B illustrates a state after an underfill 1680 is provided between the integrated device 100 and the integrated device 1600.

Stage 4 illustrates a state after an encapsulation layer 1612 is formed and coupled to the integrated device 1600. The encapsulation layer 1612 may include a mold, a resin and/or an epoxy. A compression molding process, a transfer molding process, or a liquid molding process may be used to form the encapsulation layer 1612.

Stage 5, as shown in FIG. 17C illustrates after singulation of the several integrated devices. A slicing and/or dicing operation may be used to singulate the plurality of integrated devices into a package that includes a first integrated device (e.g., 100) and a second integrated device (e.g., 1600).

Stage 6 illustrates a state after the carrier 1700 is decoupled from the package. The carrier 1700 may be detached or grinded off from the package 1690 that includes integrated device 100 and the integrated device 1600.

Exemplary Flow Diagram of a Method for Fabricating a Package Comprising Integrated Devices

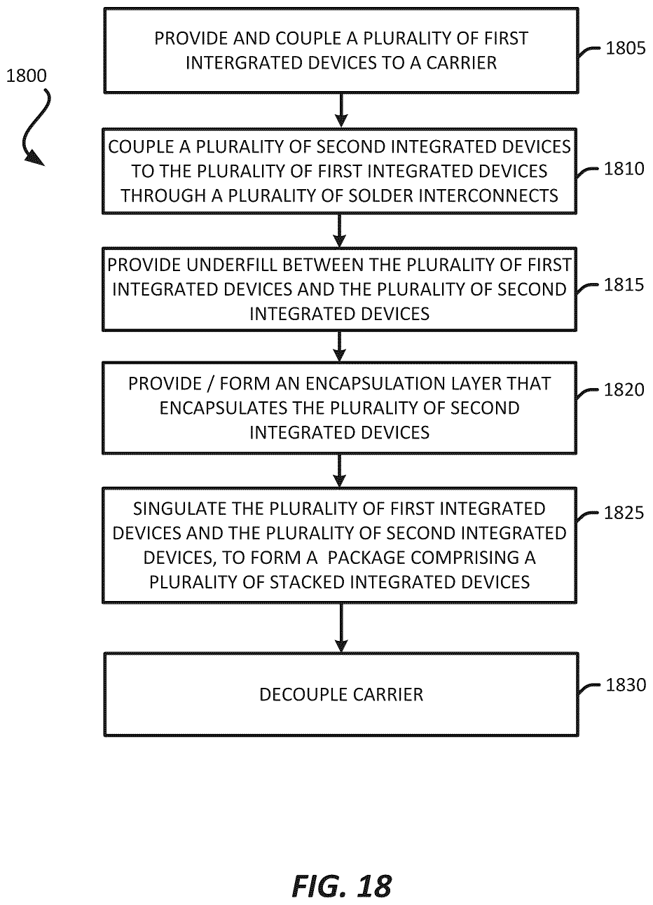

In some implementations, fabricating a package includes several processes. FIG. 18 illustrates an exemplary flow diagram of a method 1800 for providing or fabricating a package comprising integrated devices. In some implementations, the method 1800 of FIG. 18 may be used to provide or fabricate the package 1690 of FIG. 16 described in the disclosure. However, the method 1800 may be used to provide or fabricate any of the packages described in the disclosure.

It should be noted that the method of FIG. 18 may combine one or more processes in order to simplify and/or clarify the method for providing or fabricating a package. In some implementations, the order of the processes may be changed or modified.

The method provides and couples (at 1805) a plurality of first integrated devices to the carrier. Stage 1 of FIG. 17A, illustrates and describes an example of a state after several integrated devices (e.g., first integrated devices, 100) are provided and coupled to a carrier 1700. An adhesive may be used to couple the integrated device to the carrier.

The method couples (at 1810) a plurality of second integrated devices to the plurality of first integrated devices through a plurality of solder interconnects. Stage 2 of FIG. 17A, illustrates and describes an example of a state after several integrated devices (e.g., second integrated devices, 1600) are coupled to the first integrated devices (e.g., 100) through a plurality of solder interconnects (e.g., 110). A solder reflow process may be used to couple the integrated device 1600 (e.g., second integrated device) to the integrated device 100 (e.g. first integrated device).

The method provides (at 1815) an underfill between the plurality of first integrated devices and the plurality of second integrated devices. Stage 3 of FIG. 17B, illustrates and describes an example of a state after an underfill 1680 is provided between the integrated device 100 and the integrated device 1600.

The method forms (at 1820) an encapsulation layer that encapsulates the plurality of second integrated devices. The encapsulation layer may touch a side surface of the plurality of second integrated devices. Stage 4 of FIG. 17B, illustrates and describes an example of a state after an encapsulation layer 1612 is formed and coupled to the integrated device 1600. The encapsulation layer 1612 may include a mold, a resin and/or an epoxy. A compression molding process, a transfer molding process, or a liquid molding process may be used to form the encapsulation layer 1612.

The method singulates (at 1825) the plurality of first integrated devices and the plurality of second integrated devices to form a package that includes a plurality of stacked integrated devices. Stage 5 of FIG. 17C, illustrates and describes an example of a state after singulation of the several integrated devices. A slicing and/or dicing operation may be used to singulate the plurality of integrated devices into a package that includes a first integrated device (e.g., 100) and a second integrated device (e.g., 1600).

The method decouples (at 1830) the carrier from the package. Stage 6 of FIG. 17C, illustrates and describes an example of a state after the carrier 1700 is decoupled from the package. The carrier 1700 may be detached or grinded off from the package 1690 that includes integrated device 100 and the integrated device 1600.

### Exemplary Electronic Devices

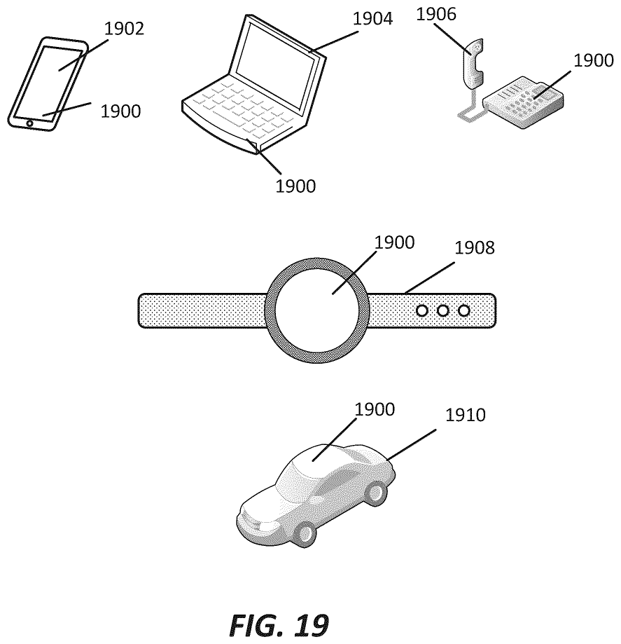

FIG. 19 illustrates various electronic devices that may be integrated with any of the aforementioned device, integrated device, integrated circuit (IC) package, integrated circuit (IC) device, semiconductor device, integrated circuit, die, interposer, package, package on package (POP), System in Package (SiP), or System on Chip (SoC). For example, a mobile phone device 1902, a laptop computer device 1904, a fixed location terminal device 1906, a wearable device 1908, or automotive vehicle 1910 may include a device 1900 as described herein. The device 1900 may be, for example, any of the devices and/or integrated circuit (IC) packages described herein. The devices 1902, 1904, 1906 and 1908 and the vehicle 1910 illustrated in FIG. 19 are merely exemplary. Other electronic devices may also feature the device 1900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-12, 13A-13I, 14-16, 17A-17C and/or 18-19 may be rearranged and/or combined into a single component, process, feature or function or embodied in several components, processes, or functions. Additional elements, components, processes, and/or functions may also be added without departing from the disclosure. It should also be noted FIGS. 1-12, 13A-13I, 14-16, 17A-17C and/or 18-19 and its corresponding description in the present disclosure is not limited to dies and/or ICs. In some implementations, FIGS. 1-12, 13A-13I, 14-16, 17A-17C and/or 18-19 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package on package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object that is coupled to another object may be coupled to at least part of the another object. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. A first component that is “located” in a second component may mean that the first component is “partially located” in the second component or “completely located” in the second component. A first component that is “embedded” in a second component may mean that the first component is “partially embedded” in the second component or “completely embedded” in the second component. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: An integrated device comprising a die substrate; a die interconnection coupled to the die substrate; an encapsulation layer coupled to a side surface of the die substrate and a side surface of the die interconnection; a plurality of pad interconnects coupled to the die interconnection; and a plurality of metallization interconnects, wherein one or more metallization interconnects from the plurality of metallization interconnects is coupled to one or more pad interconnects from the plurality of pad interconnects.

Aspect 2: The integrated device of aspect 1, wherein at least some metallization interconnects from the plurality of metallization interconnects are arranged in a hub and spoke configuration.

Aspect 3: The integrated device of aspect 2, wherein the plurality of metallization interconnects comprise a first pad metallization interconnect configured as a hub of the hub and spoke configuration; a first trace metallization interconnect coupled to the first pad metallization interconnect; a second pad metallization interconnect coupled to the first trace metallization interconnect; a second trace metallization interconnect coupled to the first pad metallization interconnect; and a third pad metallization interconnect coupled to the second trace metallization interconnect.

Aspect 4: The integrated device of aspect 3, wherein the first trace metallization interconnect and the second trace metallization interconnect each has a respective thickness that is less than a thickness of the first pad metallization interconnect.

Aspect 5: The integrated device of aspect 3, wherein the first pad metallization interconnect includes a first width that is greater than a second width of the second pad metallization interconnect.

Aspect 6: The integrated device of aspect 2, wherein the plurality of metallization interconnects comprise a first pad metallization interconnect configured as a hub of the hub and spoke configuration; a first metallization interconnect coupled to the first pad metallization interconnect; a second pad metallization interconnect coupled to the first metallization interconnect; and a third pad metallization interconnect coupled to the first metallization interconnect.

Aspect 7: The integrated device of aspect 1, wherein the die interconnection is located between the die substrate and the plurality of metallization interconnects, and wherein the encapsulation layer laterally surrounds at least part of the plurality of metallization interconnects.

Aspect 8: The integrated device of aspect 1, further comprising a passivation layer coupled to the die interconnection, wherein the encapsulation layer is coupled to the passivation layer.

Aspect 9: The integrated device of aspect 8, further comprising a solder resist layer coupled to the encapsulation layer, wherein the encapsulation layer is located between the passivation layer and the solder resist layer.

Aspect 10: The integrated device of aspect 1, wherein the integrated device is part of a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 11: A package comprising a first integrated device comprising: a die substrate; a die interconnection coupled to the die substrate; an encapsulation layer coupled to a side surface of the die substrate and a side surface of the die interconnection; a plurality of pad interconnects coupled to the die interconnection; and a plurality of metallization interconnects, wherein one or more metallization interconnects is coupled to one or more pad interconnects from the plurality of pad interconnects; and a second integrated device coupled to the first integrated device through a plurality of solder interconnects.

Aspect 12: The package of aspect 11, wherein at least some metallization interconnects from the plurality of metallization interconnects are arranged in a hub and spoke configuration.

Aspect 13: The package of aspect 12, wherein the plurality of metallization interconnects comprise a first pad metallization interconnect configured as a hub of the hub and spoke configuration; a first trace metallization interconnect coupled to the first pad metallization interconnect; a second pad metallization interconnect coupled to the first trace metallization interconnect; a second trace metallization interconnect coupled to the first pad metallization interconnect; and a third pad metallization interconnect coupled to the second trace metallization interconnect.

Aspect 14: The package of aspect 13, wherein the first trace metallization interconnect and the second trace metallization interconnect each has a respective thickness that is less than a thickness of the first pad metallization interconnect.

Aspect 15: The package of aspect 11, wherein the die interconnection is located between the die substrate and the plurality of metallization interconnects, and wherein the encapsulation layer laterally surrounds at least part of the plurality of metallization interconnects.

Aspect 16: The package of aspect 11, wherein the first integrated device comprises a first front side and a first back side, and wherein the second integrated device comprises a second front side and a second back side.

Aspect 17: The package of aspect 16, wherein the second back side of the second integrated device is coupled to the first front side of the first integrated device.

Aspect 18: The package of aspect 16, wherein the first back side of the first integrated device is coupled to the second front side of the second integrated device.

Aspect 19: The package of aspect 11, further comprising a second encapsulation layer coupled to a side surface of the second integrated device.

Aspect 20: The package of aspect 11, wherein at least some metallization interconnects from the plurality of metallization interconnects are arranged in a first hub and spoke configuration, wherein the second integrated device comprises a second plurality of metallization interconnects, and wherein some metallization interconnects from the second plurality of metallization interconnects are arranged in a second hub and spoke configuration.

Aspect 21: A device comprising: a die substrate; a die interconnection coupled to the die substrate; an encapsulation layer coupled to a side surface of the die substrate and a side surface of the die interconnection; a plurality of pad interconnects coupled to the die interconnection; and a plurality of metallization interconnects, wherein one or more metallization interconnects from the plurality of metallization interconnects is coupled to one or more pad interconnects from the plurality of pad interconnects.

Aspect 22: The device of aspect 21, wherein at least some metallization interconnects from the plurality of metallization interconnects are arranged in a hub and spoke configuration.

Aspect 23: The device of aspect 22, wherein the plurality of metallization interconnects comprise a first pad metallization interconnect configured as a hub of the hub and spoke configuration; a first trace metallization interconnect coupled to the first pad metallization interconnect; a second pad metallization interconnect coupled to the first trace metallization interconnect; a second trace metallization interconnect coupled to the first pad metallization interconnect; and a third pad metallization interconnect coupled to the second trace metallization interconnect.

Aspect 24: The device of aspect 23, wherein the first trace metallization interconnect and the second trace metallization interconnect each has a respective thickness that is less than a thickness of the first pad metallization interconnect.

Aspect 25: The device of aspect 23, wherein the first pad metallization interconnect includes a first width that is greater than a second width of the second pad metallization interconnect.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. An integrated device comprising:
a die substrate;
a die interconnection coupled to the die substrate;
an encapsulation layer coupled to a side surface of the die substrate and a side surface of the die interconnection;
a plurality of pad interconnects coupled to the die interconnection; and
a plurality of metallization interconnects, wherein one or more metallization interconnects from the plurality of metallization interconnects is coupled to one or more pad interconnects from the plurality of pad interconnects.

2. The integrated device of claim 1, wherein at least some metallization interconnects from the plurality of metallization interconnects are arranged in a hub and spoke configuration.

3. The integrated device of claim 2, wherein the plurality of metallization interconnects comprise:
a first pad metallization interconnect configured as a hub of the hub and spoke configuration;
a first trace metallization interconnect coupled to the first pad metallization interconnect;
a second pad metallization interconnect coupled to the first trace metallization interconnect;
a second trace metallization interconnect coupled to the first pad metallization interconnect; and
a third pad metallization interconnect coupled to the second trace metallization interconnect.

4. The integrated device of claim 3, wherein the first trace metallization interconnect and the second trace metallization interconnect each has a respective thickness that is less than a thickness of the first pad metallization interconnect.

5. The integrated device of claim 3, wherein the first pad metallization interconnect includes a first width that is greater than a second width of the second pad metallization interconnect.

6. The integrated device of claim 2, wherein the plurality of metallization interconnects comprise:
a first pad metallization interconnect configured as a hub of the hub and spoke configuration;
a first metallization interconnect coupled to the first pad metallization interconnect;
a second pad metallization interconnect coupled to the first metallization interconnect; and
a third pad metallization interconnect coupled to the first metallization interconnect.

7. The integrated device of claim 1,
wherein the die interconnection is located between the die substrate and the plurality of metallization interconnects, and
wherein the encapsulation layer laterally surrounds at least part of the plurality of metallization interconnects.

8. The integrated device of claim 1, further comprising a passivation layer coupled to the die interconnection, wherein the encapsulation layer is coupled to the passivation layer.

9. The integrated device of claim 8, further comprising a solder resist layer coupled to the encapsulation layer, wherein the encapsulation layer is located between the passivation layer and the solder resist layer.

10. The integrated device of claim 1, wherein the integrated device is part of a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

11. A package comprising:
a first integrated device comprising:
a die substrate;
a die interconnection coupled to the die substrate;
an encapsulation layer coupled to a side surface of the die substrate and a side surface of the die interconnection;
a plurality of pad interconnects coupled to the die interconnection; and
a plurality of metallization interconnects, wherein one or more metallization interconnects is coupled to one or more pad interconnects from the plurality of pad interconnects; and
a second integrated device coupled to the first integrated device through a plurality of solder interconnects.

12. The package of claim 11, wherein at least some metallization interconnects from the plurality of metallization interconnects are arranged in a hub and spoke configuration.

13. The package of claim 12, wherein the plurality of metallization interconnects comprise:
a first pad metallization interconnect configured as a hub of the hub and spoke configuration;
a first trace metallization interconnect coupled to the first pad metallization interconnect;
a second pad metallization interconnect coupled to the first trace metallization interconnect;
a second trace metallization interconnect coupled to the first pad metallization interconnect; and
a third pad metallization interconnect coupled to the second trace metallization interconnect.

14. The package of claim 13, wherein the first trace metallization interconnect and the second trace metallization interconnect each has a respective thickness that is less than a thickness of the first pad metallization interconnect.

15. The package of claim 11,
wherein the die interconnection is located between the die substrate and the plurality of metallization interconnects, and
wherein the encapsulation layer laterally surrounds at least part of the plurality of metallization interconnects.

16. The package of claim 11,
wherein the first integrated device comprises a first front side and a first back side, and
wherein the second integrated device comprises a second front side and a second back side.

17. The package of claim 16, wherein the second back side of the second integrated device is coupled to the first front side of the first integrated device.

18. The package of claim 16, wherein the first back side of the first integrated device is coupled to the second front side of the second integrated device.

19. The package of claim 11, further comprising a second encapsulation layer coupled to a side surface of the second integrated device.

20. The package of claim 11,
wherein at least some metallization interconnects from the plurality of metallization interconnects are arranged in a first hub and spoke configuration,
wherein the second integrated device comprises a second plurality of metallization interconnects, and
wherein some metallization interconnects from the second plurality of metallization interconnects are arranged in a second hub and spoke configuration.

21. A device comprising:
a die substrate;
a die interconnection coupled to the die substrate;
an encapsulation layer coupled to a side surface of the die substrate and a side surface of the die interconnection;
a plurality of pad interconnects coupled to the die interconnection; and
a plurality of metallization interconnects, wherein one or more metallization interconnects from the plurality of metallization interconnects is coupled to one or more pad interconnects from the plurality of pad interconnects.

22. The device of claim 21, wherein at least some metallization interconnects from the plurality of metallization interconnects are arranged in a hub and spoke configuration.

23. The device of claim 22, wherein the plurality of metallization interconnects comprise:
a first pad metallization interconnect configured as a hub of the hub and spoke configuration;
a first trace metallization interconnect coupled to the first pad metallization interconnect;
a second pad metallization interconnect coupled to the first trace metallization interconnect;
a second trace metallization interconnect coupled to the first pad metallization interconnect; and
a third pad metallization interconnect coupled to the second trace metallization interconnect.

24. The device of claim 23, wherein the first trace metallization interconnect and the second trace metallization interconnect each has a respective thickness that is less than a thickness of the first pad metallization interconnect.

25. The device of claim 23, wherein the first pad metallization interconnect includes a first width that is greater than a second width of the second pad metallization interconnect.
